(19) United States
(12) Patent Application Publication
(10) Pub. No.: US 2022/0231249 A1
(43) Pub. Date: Jul. 21, 2022

(54) LIGHT-EMITTING DEVICE, LIGHT-EMITTING APPARATUS, LIGHT-EMITTING MODULE, ELECTRONIC DEVICE, AND LIGHTING DEVICE

(71) Applicant: SEMICONDUCTOR ENERGY LABORATORY CO., LTD., ATSUGI-SHI, KANAGAWA-KEN (JP)

(72) Inventors: Takeyoshi WATABE, Atsugi, Kanagawa (JP); Airi UEDA, Sagamihara, Kanagawa (JP); Nobuharu OHSAWA, Zama, Kanagawa (JP); Satoshi SEO, Sagamihara, Kanagawa (JP)

(21) Appl. No.: 17/609,026

(22) PCT Filed: Apr. 27, 2020
(86) PCT No.: PCT/IB2020/053905

§ 371 Date: Nov. 5, 2021

(30) Foreign Application Priority Data
May 10, 2019 (JP) 2019-089524

(51) Int. Cl. H01L 51/50

(52) U.S. Cl. CPC H01L 51/5004; H01L 51/5088; H01L 51/0077; H01L 51/5056; H01L 51/5072

(57) ABSTRACT

The reliability of a light-emitting device emitting near-infrared light is increased. The light-emitting device includes a hole-injection layer, a light-emitting layer, and an electron-transport layer in this order between a pair of electrodes. The hole-injection layer contains a first compound and a second compound. The first compound has a property of accepting an electron from the second compound. The second compound has a HOMO level higher than or equal to −5.7 eV and lower than or equal to −5.4 eV. The light-emitting layer contains a light-emitting organic compound. The maximum peak wavelength of light emitted from the light-emitting organic compound is greater than or equal to 760 nm and less than or equal to 900 nm. The electron-transport layer contains a third compound and a substance containing a metal. The third compound is an electron-transport material. The substance containing a metal is a metal, a metallic salt, a metal oxide, or an organometallic salt.

### TECHNICAL FIELD

One embodiment of the present invention relates to a light-emitting device, a light-emitting apparatus, a light-emitting module, an electronic device, and a lighting device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a driving method thereof, and a manufacturing method thereof.

### BACKGROUND ART

Research and development have been actively conducted on light-emitting devices using an organic electroluminescence (EL) phenomenon (also referred to as organic EL devices or organic EL elements). In a basic structure of an organic EL device, a layer containing a light-emitting organic compound (hereinafter, also referred to as a light-emitting layer) is sandwiched between a pair of electrodes. By application of voltage to the organic EL device, light emitted from the light-emitting organic compound can be obtained.

An example of the light-emitting organic compound is a compound capable of converting a triplet excited state into light (also referred to as a phosphorescent compound or a phosphorescent material). As a phosphorescent material, Patent Document 1 discloses an organometallic complex that contains iridium or the like as a central metal.

Image sensors have been used in a variety of applications such as personal authentication, defect analysis, medical diagnosis, and security. The wavelength of light sources used for image sensors is different depending on applications. Light having a variety of wavelengths, for example, light having a short wavelength, such as visible light and X-rays, and light having a long wavelength, such as near-infrared light, is used for image sensors.

Light-emitting devices have been considered to be used as light sources of image sensors such as the above in addition to display devices.

### REFERENCE

### Patent Document

[Patent Document 1] Japanese Published Patent Application No. 2007-137872

### SUMMARY OF THE INVENTION

### Problems to be Solved by the Invention

An object of one embodiment of the present invention is to increase the reliability of a light-emitting device that emits near-infrared light. An object of one embodiment of the present invention is to increase the lifetime of a light-emitting device that emits near-infrared light. An object of one embodiment of the present invention is to increase the emission efficiency of a light-emitting device that emits near-infrared light.

Note that the description of these objects does not preclude the existence of other objects. One embodiment of the present invention does not need to achieve all these objects. Other objects can be derived from the description of the specification, the drawings, and the claims.

### Means for Solving the Problems

A light-emitting device of one embodiment of the present invention includes a hole-injection layer, a light-emitting layer, and an electron-transport layer in this order between a pair of electrodes. The hole-injection layer contains a first compound and a second compound. The first compound has a property of accepting an electron from the second compound. The second compound has a highest occupied molecular orbital level (HOMO level) higher than or equal to −5.7 eV and lower than or equal to −5.4 eV. The light-emitting layer contains a light-emitting organic compound. The maximum peak wavelength of light emitted from the light-emitting organic compound is greater than or equal to 760 nm and less than or equal to 900 nm. The electron-transport layer contains a third compound and a substance containing a metal. The third compound is an electron-transport material. The substance containing a metal is a metal, a metallic salt, a metal oxide, or an organometallic salt.

The third compound preferably has a HOMO level higher than or equal to −6.0 eV.

The electron-transport layer preferably includes a first region and a second region. The first region is preferably positioned closer to the light-emitting layer than the second region is. The first region and the second region preferably differ in a concentration of the substance containing a metal. The concentration of the substance containing a metal is preferably higher in the first region than in the second region. In that case, the second region does not necessarily contain the substance containing a metal. Alternatively, the concentration of the substance containing a metal is preferably higher in the second region than in the first region. In that case, the first region does not necessarily contain the substance containing a metal.

The light-emitting layer preferably further contains a fourth compound and a fifth compound. A combination of the fourth compound and the fifth compound preferably forms an exciplex. The fourth compound is preferably a hole-transport material. The fifth compound is preferably an electron-transport material.

The light-emitting device of one embodiment of the present invention preferably further includes a hole-transport layer. The hole-transport layer is preferably positioned between the hole-injection layer and the light-emitting layer. The hole-transport layer preferably contains a sixth compound. A HOMO level of the sixth compound is preferably lower than or equal to the HOMO level of the second compound. A difference between the HOMO level of the sixth compound and the HOMO level of the second compound is preferably 0.2 eV or less. The second compound and the sixth compound each preferably include at least one of a carbazole skeleton, a dibenzofuran skeleton, a dibenzothiophene skeleton, and an anthracene skeleton. The second compound and the sixth compound are preferably the same compound.

The substance containing a metal is preferably a metal complex containing an alkali metal or an alkaline earth metal.

The substance containing a metal is preferably a metal complex including a ligand containing nitrogen and oxygen, and an alkali metal or an alkaline earth metal.

The substance containing a metal is preferably a metal complex including a monovalent metal ion and a ligand having an 8-quinolinolato structure.

The substance containing a metal is preferably a lithium complex including a ligand having an 8-quinolinolato structure.

The light-emitting organic compound is preferably an organometallic complex having a metal-carbon bond. The organometallic complex preferably includes a condensed heteroaromatic ring including 2 to 5 rings. The condensed heteroaromatic ring is preferably coordinated to the metal.

The light-emitting organic compound is preferably a cyclometalated complex. The light-emitting organic compound is preferably an orthometalated complex. The light-emitting organic compound is preferably an iridium complex.

The maximum peak wavelength of the light emitted from the light-emitting organic compound is preferably greater than or equal to 780 nm and less than or equal to 880 nm.

One embodiment of the present invention is a light-emitting apparatus that includes the light-emitting device having any of the above-described structures, and one or both of a transistor and a substrate.

One embodiment of the present invention is a light-emitting module including the above-described light-emitting apparatus, where a connector such as a flexible printed circuit (hereinafter, referred to as FPC) or a TCP (Tape Carrier Package) is attached or an integrated circuit (IC) is mounted by a COG (Chip On Glass) method, a COF (Chip On Film) method, or the like. Note that the light-emitting module of one embodiment of the present invention may include only one of a connector and an IC or may include both of them.

One embodiment of the present invention is an electronic device including the above-described light-emitting module and at least one of an antenna, a battery, a housing, a camera, a speaker, a microphone, and an operation button.

One embodiment of the present invention is a lighting device including the above-described light-emitting apparatus and at least one of a housing, a cover, and a support.

### Effect of the Invention

According to one embodiment of the present invention, the reliability of a light-emitting device that emits near-infrared light can be increased. According to one embodiment of the present invention, the lifetime of a light-emitting device that emits near-infrared light can be increased. According to one embodiment of the present invention, the emission efficiency of a light-emitting device that emits near-infrared light can be increased.

Note that the description of these effects does not preclude the existence of other effects. One embodiment of the present invention does not need to have all these effects. Other effects can be derived from the description of the specification, the drawings, and the claims.

### BRIEF DESCRIPTION OF THE DRAWINGS

FIG. 1A to FIG. 1E are cross-sectional views illustrating examples of light-emitting devices.

FIG. 2A to FIG. 2C are conceptual diagrams each illustrating a light-emitting model of a light-emitting device.

FIG. 3A to FIG. 3D are diagrams showing the concentration of a substance containing a metal in an electron-transport layer.

FIG. 4A is a top view illustrating an example of a light-emitting apparatus. FIG. 4B and FIG. 4C are cross-sectional views illustrating examples of light-emitting apparatuses.

FIG. 5A is a top view illustrating an example of a light-emitting apparatus. FIG. 5B is a cross-sectional view illustrating an example of a light-emitting apparatus.

FIG. 6A to FIG. 6E are diagrams illustrating examples of electronic devices.

FIG. 7 is a diagram illustrating a light-emitting device in Example.

FIG. 8 is a graph showing the current density-radiant emittance characteristics of a device 1.

FIG. 9 is a graph showing the voltage-current density characteristics of the device 1.

FIG. 10 is a graph showing the current density-radiant flux characteristics of the device 1.

FIG. 11 is a graph showing the voltage-radiant emittance characteristics of the device 1.

FIG. 12 is a graph showing the current density-external quantum efficiency characteristics of the device 1.

FIG. 13 is a graph showing an emission spectrum of the device 1.

FIG. 14A and FIG. 14B are graphs showing results of a reliability test of the device 1.

FIG. 15 is a diagram illustrating a structure of an electron-only device.

FIG. 16 is a graph showing the current density-voltage characteristics of the electron-only device.

FIG. 17 is a graph showing calculated frequency characteristics of capacitance C when a direct current voltage is 7.0 V and a ratio of ZADN to Liq is 1:1.

FIG. 18 is a graph showing frequency characteristics of −ΔB when a direct current voltage is 7.0 V and a ratio of ZADN to Liq is 1:1.

FIG. 19 is a graph showing electric field strength dependence of electron mobility of organic compounds.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in the structures of the invention described below, the same portions or portions having similar functions are denoted by the same reference numerals in different drawings, and description thereof is not repeated. Furthermore, the same hatch pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be interchanged with each other depending on the case or circumstances. For example, the term “conductive layer” can be changed into the term “conductive film”. As another example, the term “insulating film” can be changed into the term “insulating layer”.

### Embodiment 1

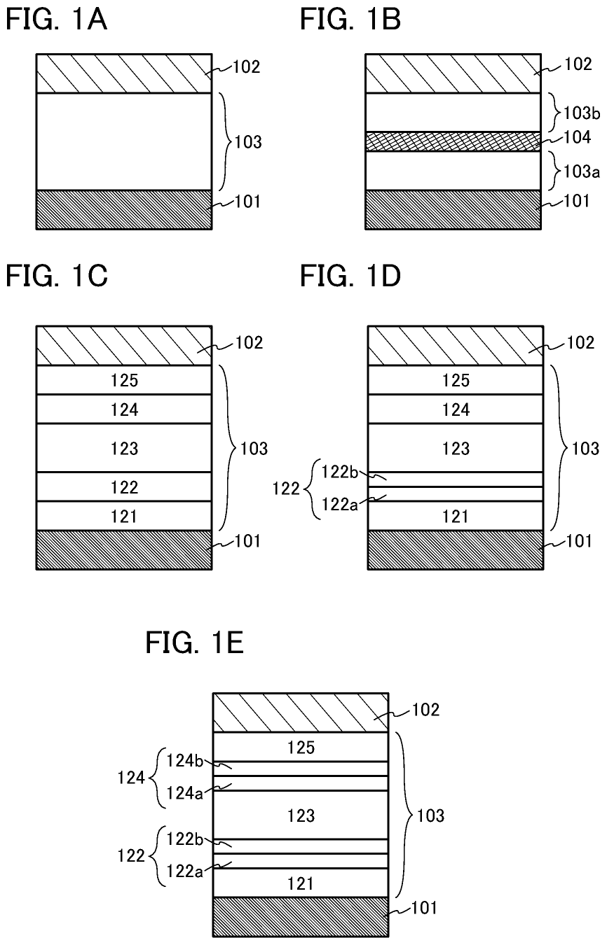

In this embodiment, a light-emitting device of one embodiment of the present invention will be described with reference to FIG. 1 to FIG. 3.

The light-emitting device of one embodiment of the present invention includes a hole-injection layer, a light-emitting layer, and an electron-transport layer in this order between a pair of electrodes (an anode and a cathode). The hole-injection layer contains a first compound and a second compound. The first compound has a property of accepting an electron from the second compound. The second compound has a HOMO level higher than or equal to −5.7 eV and lower than or equal to −5.4 eV. The electron-transport layer contains a third compound and a substance containing a metal. The third compound is a material having a high electron-transport property (also referred to as an electron-transport material). The substance containing a metal is a metal, a metallic salt, a metal oxide, or an organometallic salt.

The light-emitting device of one embodiment of the present invention has a structure in which holes are likely to be injected into the light-emitting layer and electrons are less likely to be injected into the light-emitting layer. Holes are easily injected from the anode side and the amount of electrons injected into the light-emitting layer from the cathode side is suppressed, whereby the light-emitting layer can be inhibited from having excess electrons. Moreover, injection of electrons into the light-emitting layer over time increases luminance, and the luminance increase can cancel out initial decay. Accordingly, a light-emitting device with little initial decay and an extremely long driving lifetime can be provided.

The light-emitting device of one embodiment of the present invention contains a light-emitting organic compound in the light-emitting layer. The maximum peak wavelength (also referred to as wavelength at which the peak intensity is the highest) of light emitted from the light-emitting organic compound is greater than or equal to 760 nm and less than or equal to 900 nm, preferably greater than or equal to 780 nm and preferably less than or equal to 880 nm.

The light-emitting device of one embodiment of the present invention can be formed into a film shape and is easily increased in area, and thus can be used as a planar light source that emits near-infrared light.

The light-emitting organic compound preferably exhibits phosphorescence, in which case the emission efficiency of the light-emitting device can be increased. The light-emitting organic compound is particularly preferably an organometallic complex having a metal-carbon bond. In particular, the light-emitting organic compound is further preferably a cyclometalated complex. Furthermore, the light-emitting organic compound is preferably an orthometalated complex. These organic compounds are likely to exhibit phosphorescence, and thus can increase the emission efficiency of the light-emitting device. Consequently, the light-emitting device of one embodiment of the present invention is preferably a phosphorescent device that exhibits phosphorescence.

The organometallic complex having a metal-carbon bond is suitable for the light-emitting organic compound because of its higher emission efficiency and higher chemical stability than a porphyrin-based compound and the like.

In the case where the light-emitting organic compound is used as a guest material and another organic compound is used as a host material in the light-emitting layer, when a deep trough appears (a portion with low intensity appears) in the absorption spectrum of the light-emitting organic compound, energy is not transferred smoothly from the host material to the guest material and the energy transfer efficiency is lowered, depending on the value of excitation energy of the host material. Here, in the absorption spectrum of the organometallic complex having a metal-carbon bond, many absorption bands, such as an absorption band derived from triplet MLCT (Metal to Ligand Charge Transfer) transition, an absorption band derived from singlet MLCT transition, and an absorption band derived from triplet π-π* transition, overlap with each other; hence, a deep trough is less likely to appear in the absorption spectrum. Thus, the range of the value of excitation energy of the material that can be used as the host material can be widened, and the range of choices for the host material can be widened.

In addition, the light-emitting organic compound is preferably an iridium complex. For example, the light-emitting organic compound is preferably a cyclometalated complex using iridium as the central metal. Since the iridium complex has higher chemical stability than a platinum complex and the like, the use of the iridium complex as the light-emitting organic compound can increase the reliability of the light-emitting device. In terms of such stability, a cyclometalated complex of iridium is preferable, and an orthometalated complex of iridium is further preferable.

From the viewpoint of obtaining near-infrared light emission, the ligand of the above organometallic complex preferably has a structure in which a condensed heteroaromatic ring including 2 to 5 rings is coordinated to a metal. The condensed heteroaromatic ring preferably includes 3 or more rings. Moreover, the condensed heteroaromatic ring preferably includes 4 or less rings. As the number of rings included in the condensed heteroaromatic ring increases, the LUMO level (the lowest unoccupied molecular orbital level) can be lower and the wavelength of light emitted from the organometallic complex can be longer. Meanwhile, as the number of condensed heteroaromatic rings decreases, the sublimability can be increased. Consequently, by employing a condensed heteroaromatic ring including 2 to 5 rings, the LUMO level of the ligand is adequately lowered, and the wavelength of light that is emitted from the organometallic complex and derived from the (triplet) MLCT transition can be increased to the near-infrared wavelength while high sublimability is maintained. In addition, as the number of nitrogen atoms (N) included in the condensed heteroaromatic ring increases, the LUMO level can be lower. Therefore, the number of nitrogen atoms (N) included in the condensed heteroaromatic ring is preferably two or more, particularly preferably two.

The light-emitting layer preferably further contains a fourth compound and a fifth compound. A combination of the fourth compound and the fifth compound preferably forms an exciplex. It is preferable that one of the fourth compound and the fifth compound be a hole-transport material and the other be an electron-transport material. With such a structure, the emission efficiency of the light-emitting device can be increased.

### [Structure Example of Light-Emitting Device]

### <<Basic Structure of Light-Emitting Device>>

FIG. 1A to FIG. 1E illustrate examples of light-emitting devices including an EL layer between a pair of electrodes.

The light-emitting device illustrated in FIG. 1A has a structure in which an EL layer 103 is provided between a first electrode 101 and a second electrode 102 (a single structure). The EL layer 103 includes at least a light-emitting layer.

A light-emitting device may include a plurality of EL layers between a pair of electrodes. FIG. 1B illustrates a light-emitting device having a tandem structure in which two EL layers (an EL layer 103a and an EL layer 103b) are provided between a pair of electrodes and a charge-generation layer 104 is provided between the two EL layers. The light-emitting device having a tandem structure can be driven at low voltage and have low power consumption.

The charge-generation layer 104 has a function of injecting electrons into one of the EL layer 103a and the EL layer 103b and injecting holes into the other when voltage is applied to the first electrode 101 and the second electrode 102. Thus, when voltage is applied in FIG. 1B such that the potential of the first electrode 101 is higher than that of the second electrode 102, the charge-generation layer 104 injects electrons into the EL layer 103a and injects holes into the EL layer 103b.

Note that in terms of light extraction efficiency, the charge-generation layer 104 preferably transmits near-infrared light (specifically, the near-infrared light transmittance of the charge-generation layer 104 is preferably 40% or higher). Furthermore, the charge-generation layer 104 functions even when having lower conductivity than the first electrode 101 and the second electrode 102.

FIG. 1C to FIG. 1E each illustrate an example of a stacked-layer structure of the EL layer 103. In this embodiment, the case where the first electrode 101 functions as an anode and the second electrode 102 functions as a cathode is described as an example.

The light-emitting devices illustrated in FIG. 1C to FIG. 1E each include a hole-injection layer 121, a hole-transport layer 122, a light-emitting layer 123, an electron-transport layer 124, and an electron-injection layer 125 from the first electrode 101 side as the EL layer 103. Although not illustrated in FIG. 1C to FIG. 1E, the light-emitting devices may each include an optical adjustment layer.

The first electrode 101, the second electrode 102, the hole-injection layer 121, the hole-transport layer 122, the light-emitting layer 123, the electron-transport layer 124, and the electron-injection layer 125 may each have a single-layer structure or a stacked-layer structure. Note that in the case where a plurality of EL layers are provided as in the tandem structure illustrated in FIG. 1B, each of the EL layers can have a stacked-layer structure similar to that of the EL layer 103 illustrated in FIG. 1C to FIG. 1E. When the first electrode 101 serves as a cathode and the second electrode 102 serves as an anode, the stacking order is reversed.

The hole-transport layer 122 included in each of the light-emitting devices illustrated in FIG. 1D and FIG. 1E has a two-layer structure of a hole-transport layer 122a on the hole-injection layer 121 side and a hole-transport layer 122b on the light-emitting layer 123 side.

The electron-transport layer 124 included in the light-emitting device illustrated in FIG. 1E has a two-layer structure of an electron-transport layer 124a on the light-emitting layer 123 side and an electron-transport layer 124b on the electron-injection layer 125 side.

The light-emitting layer 123 contains a light-emitting substance and a plurality of substances in appropriate combination, whereby fluorescence or phosphorescence with a desired wavelength can be obtained. Furthermore, the light-emitting layer 123 may be a stack of layers having different emission wavelengths. In that case, the light-emitting substance and other substances are different between the stacked light-emitting layers. The EL layer 103a and the EL layer 103b illustrated in FIG. 1B may be configured to exhibit different wavelengths. Also in that case, the light-emitting substance and other substances are different between the light-emitting layers.

The light-emitting device of one embodiment of the present invention may be configured such that light obtained from the EL layer is resonated between the pair of electrodes in order to intensify the light. For example, when the first electrode 101 is formed as a reflective electrode (an electrode having a property of reflecting near-infrared light) and the second electrode 102 is formed as a transflective electrode (an electrode having properties of transmitting and reflecting near-infrared light) in FIG. 1C to form a micro optical resonator (microcavity) structure, light obtained from the EL layer 103 can be intensified.

Note that in the case where the first electrode 101 of the light-emitting device is a reflective electrode having a stacked-layer structure of a conductive film having a property of reflecting near-infrared light and a conductive film having a property of transmitting near-infrared light, optical adjustment can be performed by controlling the thickness of the conductive film having the transmitting property. Specifically, when the wavelength of light obtained from the light-emitting layer 123 is λ, the distance between the first electrode 101 and the second electrode 102 is preferably adjusted to around mλ/2 (m is a natural number).

To amplify desired light (wavelength: λ) obtained from the light-emitting layer 123, the optical distance from the first electrode 101 to a region where the desired light is obtained in the light-emitting layer 123 (a light-emitting region) and the optical distance from the second electrode 102 to the region where the desired light is obtained in the light-emitting layer 123 (the light-emitting region) are preferably adjusted to around (2m′+1)λ/4 (m′ is a natural number). Here, the light-emitting region refers to a region where holes and electrons are recombined in the light-emitting layer 123.

By performing such optical adjustment, the spectrum of light obtained from the light-emitting layer 123 can be narrowed, and light with a desired wavelength can be obtained.

Note that in the above case, the optical distance between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained with given positions in the first electrode 101 and the second electrode 102 being supposed to be reflective regions. Furthermore, the optical distance between the first electrode 101 and the light-emitting layer from which the desired light is obtained is, to be exact, the optical distance between the reflective region in the first electrode 101 and the light-emitting region in the light-emitting layer from which the desired light is obtained. However, it is difficult to precisely determine the reflective region in the first electrode 101 and the light-emitting region in the light-emitting layer from which the desired light is obtained; thus, it is assumed that the above effect can be sufficiently obtained with a given position in the first electrode 101 being supposed to be the reflective region and a given position in the light-emitting layer from which the desired light is obtained being supposed to be the light-emitting region.

At least one of the first electrode 101 and the second electrode 102 has a property of transmitting near-infrared light. The transmissivity of near-infrared light of the electrode having a property of transmitting near-infrared light is higher than or equal to 40%. In the case where the electrode having a property of transmitting near-infrared light is the above-described transflective electrode, the near-infrared light reflectance of the electrode is higher than or equal to 20%, preferably higher than or equal to 40% and lower than 100%, preferably lower than or equal to 95%, and may be lower than or equal to 80% or lower than or equal to 70%. For example, the near-infrared light reflectance of the electrode is higher than or equal to 20% and lower than or equal to 80%, preferably higher than or equal to 40% and preferably lower than or equal to 70%. The electrode preferably has a resistivity of 1×10⁻² Ωcm or less.

When the first electrode 101 or the second electrode 102 is the reflective electrode, the near-infrared light reflectance of the reflective electrode is higher than or equal to 40% and lower than or equal to 100%, preferably higher than or equal to 70% and lower than or equal to 100%. This electrode preferably has a resistivity of 1×10⁻² Ωcm or less.

### <<Material and Fabrication Method of Light-Emitting Device>>

Next, materials and a fabrication method that can be used for the light-emitting device will be described. Here, the light-emitting device having the single structure illustrated in FIG. 1E is used for the description.

### <Electrode>

As materials for forming the pair of electrodes of the light-emitting device, any of the following materials can be used in an appropriate combination as long as the functions of the electrodes described above can be fulfilled. For example, a metal, an alloy, an electrically conductive compound, a mixture of these, and the like can be used as appropriate. Specific examples include an In—Sn oxide (also referred to as ITO), an In—Si—Sn oxide (also referred to as ITSO), an In—Zn oxide, and an In—W—Zn oxide. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these, graphene, or the like.

Note that when a light-emitting device having a microcavity structure is formed, one of the first electrode 101 and the second electrode 102 is formed as a reflective electrode and the other is formed as a transflective electrode. Thus, a single layer or stacked layers can be formed using one or more desired conductive materials. Note that the second electrode 102 is formed after formation of the EL layer 103, with the use of a material selected as described above. For fabrication of these electrodes, a sputtering method or a vacuum evaporation method can be used.

### <Hole-Injection Layer>

The hole-injection layer 121 has a function of facilitating injection of holes into the EL layer 103. For example, the hole-injection layer 121 can have a function of injecting holes, which are injected from the anode, into the hole-transport layer 122 (or the light-emitting layer 123 or the like). For example, the hole-injection layer 121 can have a function of generating holes and injecting the holes into the hole-transport layer 122 (or the light-emitting layer 123 or the like).

The first compound is an electron-accepting material (an acceptor material) and has a property of accepting electrons from the second compound.

The second compound is a hole-transport material. The hole-transport material has a hole-transport property higher than an electron-transport property.

The HOMO level of the second compound is preferably relatively low (deep). Specifically, the HOMO level of the second compound is preferably higher than or equal to −5.7 eV and lower than or equal to −5.4 eV. A relatively low HOMO level of the second compound is preferable because hole injection into the hole-transport layer 122 can be easily performed.

As the first compound, an organic compound including an electron-withdrawing group (in particular, a cyano group or a halogen group such as a fluoro group) can be used.

For example, as the first compound, organic acceptors such as a quinodimethane derivative, a chloranil derivative, and a hexaazatriphenylene derivative can be used. Specific examples include 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. Alternatively, a [3]radialene derivative including an electron-withdrawing group (in particular, a cyano group or a halogen group such as a fluoro group) is preferable because it has a very high electron-accepting property. Examples of the [3]radialene derivative including an electron-withdrawing group include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

The second compound preferably includes a hole-transport skeleton. A carbazole skeleton, a dibenzofuran skeleton, a dibenzothiophene skeleton, and an anthracene skeleton, with which the HOMO levels of the hole-transport materials do not become too high (shallow), are preferably used as the hole-transport skeleton.

The second compound preferably includes at least one of a carbazole skeleton, a dibenzofuran skeleton, a dibenzothiophene skeleton, and an anthracene skeleton. The hole-transport material may be an aromatic amine including a substituent that includes a dibenzofuran ring or a dibenzothiophene ring, an aromatic monoamine that includes a naphthalene ring, or an aromatic monoamine in which a 9-fluorenyl group is bonded to nitrogen of the amine through an arylene group.

The second compound including an N,N-bis(4-biphenyl)amino group is preferred because a light-emitting device having a long lifetime can be fabricated.

Examples of the second compound include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II) (4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenylyl)carbazole)}triphenylamine (abbreviation: YGTBiβNB), N-[4-(9-phenyl-9H-carbazol-3-yl)phenyl]-N-[4-(1-naphthyl)phenyl]-9,9′-spirobi(9H-fluoren)-2-amine (abbreviation: PCBNBSF), N,N-bis(4-biphenylyl)-9,9′-spirobi[9H-fluoren]-2-amine (abbreviation: BBASF), N,N-bis(1,1′-biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)-4-amine (abbreviation: oFBiSF), N-(4-biphenyl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-9,9-dimethyl-N-[4-(9-phenyl-9H-carbazol-3-yl)phenyl]-9H-fluoren-2-amine (abbreviation: PCBBiF), 3,3′-(naphthalene-1,4-diyl)bis(9-phenyl-9H-carbazole) (abbreviation: PCzN2), and 4-(10-phenyl-9-anthryl)-4′-(9-phenyl-9H-fluoren-9-yl)triphenylamine (abbreviation: FLPAPA).

### <Hole-Transport Layer>

The hole-transport layer 122 is a layer that transports holes, which are injected by the hole-injection layer 121, to the light-emitting layer 123.

The hole-transport layer 122 preferably contains a sixth compound.

The sixth compound is a hole-transport material. As the hole-transport material, a hole-transport material that can be used as the second compound can be used.

The HOMO level of the sixth compound is preferably lower than or equal to the HOMO level of the second compound. A difference between the HOMO level of the sixth compound and the HOMO level of the second compound is preferably 0.2 eV or less.

It is preferable that the second compound and the sixth compound each include at least one of a carbazole skeleton, a dibenzofuran skeleton, a dibenzothiophene skeleton, and an anthracene skeleton.

It is preferable that the second compound and the sixth compound include the same hole-transport skeleton (especially a dibenzofuran skeleton), in which case holes can be injected smoothly.

It is further preferable that the second compound and the sixth compound be the same compound, in which case holes can be injected smoothly.

In the case where the hole-transport layer 122 has a stacked-layer structure, each of the layers included in the hole-transport layer 122 is a layer that transports holes to the light-emitting layer 123.

The hole-transport layer 122a in FIG. 1D and FIG. 1E can have a structure similar to that of the hole-transport layer 122 in FIG. 1C.

The hole-transport layer 122b in FIG. 1D and FIG. 1E (i.e., the layer in the hole-transport layer 122 which is positioned closest to the light-emitting layer 123) preferably has a function of an electron-blocking layer.

The hole-transport layer 122b preferably contains a seventh compound.

The seventh compound is a hole-transport material. As the hole-transport material, a hole-transport material that can be used as the second compound can be used.

A difference between the HOMO level of the seventh compound and the HOMO level of the sixth compound is preferably 0.2 eV or less.

It is preferable that the second compound, the sixth compound, and the seventh compound each include at least one of a carbazole skeleton, a dibenzofuran skeleton, a dibenzothiophene skeleton, and an anthracene skeleton.

It is preferable that the second compound, the sixth compound, and the seventh compound include the same hole-transport skeleton (especially a dibenzofuran skeleton), in which case holes can be injected smoothly.

Owing to the above-described relation between the hole-transport materials used for the hole-injection layer 121, the hole-transport layer 122a, and the hole-transport layer 122b, holes can be injected into each layer smoothly, which can prevent an increase in driving voltage and deficiency of holes in the light-emitting layer 123.

### <Light-Emitting Layer>

The light-emitting layer 123 is a layer containing a light-emitting substance.

The light-emitting device of one embodiment of the present invention contains a light-emitting organic compound as the light-emitting substance. The light-emitting organic compound emits near-infrared light. Specifically, the maximum peak wavelength of light emitted from the light-emitting organic compound is greater than or equal to 760 nm and less than or equal to 900 nm, preferably greater than or equal to 780 nm and preferably less than or equal to 880 nm.

As the light-emitting organic compound that emits near-infrared light, any of organometallic complexes described in Embodiment 2 can be used, for example.

The light-emitting layer 123 can contain one or more kinds of light-emitting substances.

The light-emitting device of one embodiment of the present invention may contain a light-emitting substance other than the light-emitting substance that emits near-infrared light. For example, the light-emitting device of one embodiment of the present invention may contain a light-emitting substance that emits visible light (of red, blue, green, or the like) in addition to the light-emitting substance that emits near-infrared light.

The light-emitting layer 123 may contain one or more kinds of organic compounds (e.g., a host material and an assist material) in addition to the light-emitting substance (guest material). As the one or more kinds of organic compounds, one or both of the hole-transport material and the electron-transport material described in this embodiment can be used. Alternatively, as the one or more kinds of organic compounds, a bipolar material may be used.

There is no particular limitation on the light-emitting substance that can be used for the light-emitting layer 123, and it is possible to use a light-emitting substance that converts singlet excitation energy into light in the near-infrared light range or a light-emitting substance that converts triplet excitation energy into light in the near-infrared light range.

As an example of the light-emitting substance that converts singlet excitation energy into light, a substance that exhibits fluorescence (a fluorescent material) can be given; examples include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-diphenyl-N,N′-bis[4-(9-phenyl-9H-fluoren-9-yl)phenyl]pyrene-1,6-diamine (abbreviation: 1,6FLPAPm), N,N′-bis(dibenzofuran-2-yl)-N,N′-diphenylpyrene-1,6-diamine (abbreviation: 1,6FrAPrn), N,N′-bis(dibenzothiophen-2-yl)-N,N′-diphenylpyrene-1,6-diamine (abbreviation: 1,6ThAPrn), N,N′-(pyrene-1,6-diyl)bis[(N-phenylbenzo[b]naphtho[1,2-d]furan)-6-amine] (abbreviation: 1,6BnfAPrn), N,N′-(pyrene-1,6-diyl)bis[(N-phenylbenzo[b]naphtho[1,2-d]furan)-8-amine](abbreviation: 1,6BnfAPm-02), and N,N′-(pyrene-1,6-diyl)bis[(6,N-diphenylbenzo[b]naphtho[1,2-d]furan)-8-amine] (abbreviation: 1,6BnfAPm-03). Condensed aromatic diamine compounds typified by pyrenediamine compounds such as 1,6FLPAPm, 1,6mMemFLPAPrn, and 1,6BnfAPm-03 are particularly preferable because of their high hole-trapping properties, high emission efficiency, and high reliability.

In addition, it is possible to use 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra(tert-butyl)perylene (abbreviation: TBP), N,N′-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), or the like.

Examples of the light-emitting substance that converts triplet excitation energy into light include a substance that exhibits phosphorescence (a phosphorescent material) and a thermally activated delayed fluorescence (TADF) material that exhibits thermally activated delayed fluorescence.

Examples of the phosphorescent material include an organometallic complex (especially an iridium complex) including a 4H-triazole skeleton, a 1H-triazole skeleton, an imidazole skeleton, a pyrimidine skeleton, a pyrazine skeleton, or a pyridine skeleton; an organometallic complex (especially an iridium complex) in which a phenylpyridine derivative including an electron-withdrawing group is a ligand; a platinum complex; and a rare earth metal complex.

As a phosphorescent material that exhibits blue or green and whose emission spectrum has a peak wavelength at greater than or equal to 450 nm and less than or equal to 570 nm, the following substances can be given.

The examples include organometallic complexes including a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: Ir(iPr5btz)₃]); organometallic complexes including a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic complexes including an imidazole skeleton, such as fac-tris[1-(2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Ir(dmpimpt-Me)₃]); and organometallic complexes in which a phenylpyridine derivative including an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)).

As a phosphorescent material that exhibits green or yellow and whose emission spectrum has a peak wavelength at greater than or equal to 495 nm and less than or equal to 590 nm, the following substances can be given.

The examples include organometallic iridium complexes including a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbomyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN3]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes including a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes including a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C²′)iridium(III) acetylacetonate (abbreviation: [Ir(pq)₂(acac)]), [2-(4-phenyl-2-pyridinyl-KN)phenyl-κC]bis[2-(2-pyridinyl-N)phenyl-κC]iridium(III) (abbreviation: [Ir(ppy)₂(4dppy)]), and bis[2-(2-pyridinyl-κN)phenyl-κC][2-(4-methyl-5-phenyl-2-pyridinyl-κN)phenyl-κC]; organometallic complexes such as bis(2,4-diphenyl-1,3-oxazolato-N,C^{2′})iridium(III) acetylacetonate (abbreviation: [Ir(dpo)₂(acac)]), bis{2-[4′-(perfluorophenyl)phenyl]pyridinato-N,C²′}iridium(III) acetylacetonate (abbreviation: [Ir(p-PF-ph)₂(acac)]), and bis(2-phenylbenzothiazolato-N,C^{2′})iridium(III) acetylacetonate (abbreviation: [Ir(bt)₂(acac)]); and rare earth metal complexes such as tris(acetylacetonato) (monophenanthroline)terbium(III) (abbreviation: [Tb(acac)₃(Phen)]).

As a phosphorescent material that exhibits yellow or red and whose emission spectrum has a peak wavelength at greater than or equal to 570 nm and less than or equal to 750 nm, the following substances can be given.

The examples include organometallic complexes including a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(dlnpm)₂(dpm)]), and tris(4-t-butyl-6-phenylpyrimidinato)iridium(III) (abbreviation: [Ir(tBuppm)₃]); organometallic complexes including a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-κN]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), (acetylacetonato)bis[2-methyl-3-phenylquinoxalinato-N,C^{2′}]iridium(III) (abbreviation: [Ir(mpq)₂(acac)]), (acetylacetonato)bis(2,3-diphenylquinoxalinato-N,C^{2′})iridium(III) (abbreviation: [Ir(dpq)₂(acac)]), (acetylacetonato)bis[2,3-bis(4-fluorophenyl)quinoxalinato]iridium(III) (abbreviation: [Ir(Fdpq)₂(acac)]), and bis{4,6-dimethyl-2-[5-(5-cyano-2-methylphenyl)-3-(3,5-dimethylphenyl)-2-pyrazinyl-N]phenyl-κC}(2,2,6,6-tetramethyl-3,5-heptanedionato-κ²O,O′)iridium(III) (abbreviation: [Ir(dmdppr-m5CP)₂(dpm)]); organometallic complexes including a pyridine skeleton, such as tris(1-phenylisoquinolinato-N,C²′)iridium(III) (abbreviation: [Ir(piq)₃]), bis(1-phenylisoquinolinato-N,C^{2′})iridium(III) acetylacetonate (abbreviation: [Ir(piq)₂(acac)]), and bis[4,6-dimethyl-2-(2-quinolinyl-κN)phenyl-κC] (2,4-pentanedionato-κ²O,O′)iridium(III); platinum complexes such as 2,3,7,8,12,13,17,18-octaethyl-21H,23H-porphyrinplatinum(II) (abbreviation: [PtOEP]); and rare earth metal complexes such as tris(1,3-diphenyl-1,3-propanedionato) (monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]).

As the organic compounds (e.g., the host material and the assist material) used in the light-emitting layer 123, one or more kinds of substances having a larger energy gap than the light-emitting substance can be selected and used.

In the case where the light-emitting substance used in the light-emitting layer 123 is a fluorescent material, an organic compound used in combination with the light-emitting substance is preferably an organic compound that has a high energy level in a singlet excited state and has a low energy level in a triplet excited state.

In terms of a preferable combination with the light-emitting substance (the fluorescent material or the phosphorescent material), specific examples of the organic compounds are shown below though some of them overlap the specific examples shown above.

Examples of the organic compound that can be used in combination with the fluorescent material include condensed polycyclic aromatic compounds, such as an anthracene derivative, a tetracene derivative, a phenanthrene derivative, a pyrene derivative, a chrysene derivative, and a dibenzo[g,p]chrysene derivative.

Specific examples of the organic compound (host material) used in combination with the fluorescent material include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), PCPN, 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), 4-(9H-carbazol-9-yl)-4′-(10-phenyl-9-anthryl)triphenylamine (abbreviation: YGAPA), N,9-diphenyl-N-[4-(10-phenyl-9-anthryl)phenyl]-9H-carbazol-3-amine (abbreviation: PCAPA), N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N′,N′,N″,N″,N″′,N″′-octaphenyldibenzo[g,p]chrysene-2,7,10,15-tetraamine (abbreviation: DBC1), CzPA, 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, 5,12-bis(biphenyl-2-yl)tetracene, and 9-(1-naphthyl)-10-[4-(2-naphthyl)phenyl]anthracene (abbreviation: αN-βNPAnth).

As the organic compound used in combination with the phosphorescent material, an organic compound whose triplet excitation energy (energy difference between a ground state and a triplet excited state) is higher than the triplet excitation energy of the light-emitting substance is selected.

In the case where a plurality of organic compounds (e.g., a first host material and a second host material (or an assist material)) are used in combination with the light-emitting substance in order to form an exciplex, the plurality of organic compounds are preferably mixed with a phosphorescent material (in particular, an organometallic complex).

Such a structure makes it possible to efficiently obtain light emission utilizing ExTET (Exciplex-Triplet Energy Transfer), which is energy transfer from an exciplex to a light-emitting substance. Note that a combination of a plurality of organic compounds that easily forms an exciplex is preferable, and it is particularly preferable to combine a compound that easily accepts holes (a hole-transport material) and a compound that easily accepts electrons (an electron-transport material). When a combination of materials is selected so as to form an exciplex that exhibits light emission whose wavelength overlaps the wavelength on a lowest-energy-side absorption band of the light-emitting substance, energy can be transferred smoothly and light emission can be obtained efficiently. As the hole-transport material and the electron-transport material, specifically, any of the materials described in this embodiment can be used. With this structure, high efficiency, low-voltage driving, and a long lifetime of the light-emitting device can be achieved at the same time.

In a combination of materials for forming an exciplex, the HOMO level of the hole-transport material is preferably higher than or equal to the HOMO level of the electron-transport material. The LUMO level of the hole-transport material is preferably higher than or equal to the LUMO level of the electron-transport material. The LUMO levels and the HOMO levels of the materials can be derived from the electrochemical characteristics (the reduction potentials and the oxidation potentials) of the materials that are measured by cyclic voltammetry (CV) measurement.

The formation of an exciplex can be confirmed by a phenomenon in which the emission spectrum of a mixed film in which the hole-transport material and the electron-transport material are mixed is shifted to the longer wavelength side than the emission spectrum of each of the materials (or has another peak on the longer wavelength side), observed by comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed by comparison of the transient EL of the hole-transport material, the transient EL of the electron-transport material, and the transient EL of the mixed film of these materials.

Examples of the organic compound that can be used in combination with the phosphorescent material include an aromatic amine (a compound including an aromatic amine skeleton), a carbazole derivative (a compound including a carbazole skeleton), a dibenzothiophene derivative (a thiophene derivative), a dibenzofuran derivative (a furan derivative), a zinc- or aluminum-based metal complex, an oxadiazole derivative, a triazole derivative, a benzimidazole derivative, a quinoxaline derivative, a dibenzoquinoxaline derivative, a pyrimidine derivative, a triazine derivative, a pyridine derivative, a bipyridine derivative, and a phenanthroline derivative.

As specific examples of the aromatic amine, the carbazole derivative, the dibenzothiophene derivative, and the dibenzofuran derivative, which are organic compounds having a high hole-transport property, the following substances can be given.

Specific examples of the bicarbazole derivative (e.g., a 3,3′-bicarbazole derivative) include 3,3′-bis(9-phenyl-9H-carbazole) (abbreviation: PCCP), 9,9′-bis(1,1′-biphenyl-4-yl)-3,3′-bi-9H-carbazole, 9,9′-bis(1,1′-biphenyl-3-yl)-3,3′-bi-9H-carbazole, 9-(1,1′-biphenyl-3-yl)-9′-(1,1′-biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: PNCCP).

Specific examples of the aromatic amine including a carbazolyl group include PCBA1BP, N-(4-biphenyl)-N-(9,9-dimethyl-9H-fluoren-2-yl)-9-phenyl-9H-carbazol-3-amine (abbreviation: PCBiF), PCBBiF, PCBBi1BP, PCBANB, PCBNBB, 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N′,N″-triphenyl-N,N′,N″-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), PCBASF, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino]spiro-9,9′-bifluorene (abbreviation: PCASF), N-[4-(9H-carbazol-9-yl)phenyl]-N-(4-phenyl)phenylaniline (abbreviation: YGA1BP), N,N′-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

In addition to the above, other examples of the carbazole derivative include 3-[4-(9-phenanthryl)-phenyl]-9-phenyl-9H-carbazole (abbreviation: PCPPn), PCPN, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and CzPA.

Specific examples of the thiophene derivative (a compound including a thiophene skeleton) and the furan derivative (a compound including a furan skeleton) include compounds including a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV), and 4-{3-[3-(9-phenyl-9H-fluoren-9-yl)phenyl]phenyl}dibenzofuran (abbreviation: mmDBFFLBi-II).

Specific examples of the aromatic amine include 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), BPAFLP, mBPAFLP, N-(9,9-dimethyl-9H-fluoren-2-yl)-N-{9,9-dimethyl-2-[N′-phenyl-N′-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 2,7-bis[N-(4-diphenylaminophenyl)-N-phenylamino]spiro-9,9′-bifluorene (abbreviation: DPA2SF), 4,4′,4″-tris[N-(1-naphthyl)-N-phenylamino]triphenylamine (abbreviation: 1′-TNATA), TDATA, m-MTDATA, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

As the organic compound having a high hole-transport property, a high molecular compound such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can also be used.

Specific examples of the zinc- and aluminum-based metal complexes, which are organic compounds having a high electron-transport property, include metal complexes including a quinoline skeleton or a benzoquinoline skeleton, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), and bis(8-quinolinolato)zinc(II) (abbreviation: Znq).

A metal complex having an oxazole-based or thiazole-based ligand, such as bis[2-(2-benzoxazolyl)phenolato]zinc(II) (abbreviation: ZnPBO) or bis[2-(2-benzothiazolyl)phenolato]zinc(II) (abbreviation: ZnBTZ), or the like can also be used.

Specific examples of the oxadiazole derivative, the triazole derivative, the benzimidazole derivative, the benzimidazole derivative, the quinoxaline derivative, the dibenzoquinoxaline derivative, and the phenanthroline derivative, which are organic compounds having a high electron-transport property, include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2-{4-[9,10-di(naphthalen-2-yl)-2-anthryl]phenyl}-1-phenyl-1H-benzimidazole (abbreviation: ZADN), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), 4,4′-bis(5-methylbenzoxazol-2-yl)stilbene (abbreviation: BzOs, bathophenanthroline (abbreviation: Bphen), bathocuproine (abbreviation: BCP), 2,9-bis(naphthalen-2-yl)-4,7-diphenyl-1,10-phenanthroline (abbreviation: NBphen), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), and 6-[3-(dibenzothiophen-4-yl)phenyl]dibenzo[f,h]quinoxaline (abbreviation: 6mDBTPDBq-II).

Specific examples of a heterocyclic compound having a diazine skeleton, a heterocyclic compound having a triazine skeleton, and a heterocyclic compound having a pyridine skeleton, which are organic compounds having a high electron-transport property, include 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 3,5-bis[3-(9H-carbazol-9-yl)phenyl]pyridine (abbreviation: 35DCzPPy), and 1,3,5-tri[3-(3-pyridyl)phenyl]benzene (abbreviation: TmPyPB).

As the organic compound having a high electron-transport property, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can also be used.

The TADF material is a material that has a small difference between the S₁ level (the energy level in a singlet excited state) and the T₁ level (the energy level in a triplet excited state) and has a function of converting triplet excitation energy into singlet excitation energy by reverse intersystem crossing. Thus, it is possible to upconvert triplet excitation energy into singlet excitation energy (reverse intersystem crossing) using a little thermal energy and to efficiently generate a singlet excited state. In addition, the triplet excitation energy can be converted into light emission. Thermally activated delayed fluorescence is efficiently obtained under the condition where the difference in energy between the S₁ level and the T₁ level is greater than or equal to 0 eV and less than or equal to 0.2 eV, preferably greater than or equal to 0 eV and less than or equal to 0.1 eV. Delayed fluorescence by the TADF material refers to light emission having a spectrum similar to that of normal fluorescence and an extremely long lifetime. The lifetime is 10⁻⁶ seconds or longer, preferably 10⁻³ seconds or longer.

An exciplex whose excited state is formed by two kinds of substances has an extremely small difference between the S₁ level and the T₁ level and functions as a TADF material that can convert triplet excitation energy into singlet excitation energy.

A phosphorescent spectrum observed at low temperatures (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between S₁ and T₁ of the TADF material is preferably less than or equal to 0.3 eV, further preferably less than or equal to 0.2 eV.

The TADF material may be used as a guest material or may be used as a host material.

Examples of the TADF material include fullerene, a derivative thereof, an acridine derivative such as proflavine, and eosin. Other examples include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

Other than these, a heterocyclic compound having a π-electron rich heteroaromatic ring and a π-electron deficient heteroaromatic ring, such as 2-(biphenyl-4-yl)-4,6-bis(12-phenylindolo[2,3-a]carbazol-11-yl)-1,3,5-triazine (abbreviation: PIC-TRZ), PCCzPTzn, 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-3,3′-bi-9H-carbazol-9-yl)benzofuro[3,2-d]pyrimidine (abbreviation: 4PCCzBfpm), 4-[4-(9′-phenyl-3,3′-bi-9H-carbazol-9-yl)phenyl]benzofuro[3,2-d]pyrimidine (abbreviation: 4PCCzPBfpm), or 9-[3-(4,6-diphenyl-1,3,5-triazin-2-yl)phenyl]-9′-phenyl-2,3′-bi-9H-carbazole (abbreviation: mPCCzPTzn-02) can be used. The heterocyclic compound is preferable because of having both a high electron-transport property and a high hole-transport property owing to a it-electron rich heteroaromatic ring and a it-electron deficient heteroaromatic ring. Note that an aromatic ring to which an electron-withdrawing group such as a cyano group is bonded may be used instead of the it-electron deficient heteroaromatic ring. Furthermore, a it-electron deficient skeleton can be used instead of the it-electron deficient heteroaromatic ring. Similarly, a π-electron rich skeleton can be used instead of the it-electron rich heteroaromatic ring.

Among skeletons having a it-electron deficient heteroaromatic ring, a pyridine skeleton, a diazine skeleton (a pyrimidine skeleton, a pyrazine skeleton, or a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-accepting properties and reliability.

Among skeletons having a it-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton, a dibenzothiophene skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which a π-electron rich heteroaromatic ring is directly bonded to a π-electron deficient heteroaromatic ring is particularly preferable because both the donor property of the it-electron rich heteroaromatic ring and the acceptor property of the it-electron deficient heteroaromatic ring are improved and the energy difference between the singlet excited state and the triplet excited state becomes small.

As a it-electron rich skeleton, an aromatic amine skeleton, a phenazine skeleton, or the like can be used. As a it-electron deficient skeleton, a xanthene skeleton, a thioxanthene dioxide skeleton, an oxadiazole skeleton, a triazole skeleton, an imidazole skeleton, an anthraquinone skeleton, a boron-containing skeleton such as phenylborane or boranthrene, an aromatic ring or a heteroaromatic ring having a nitrile group or a cyano group, such as benzonitrile or cyanobenzene, a carbonyl skeleton such as benzophenone, a phosphine oxide skeleton, a sulfone skeleton, or the like can be used.

Note that the TADF material can also be used in combination with another organic compound when used as a light-emitting substance. In particular, the TADF material can be combined with the host material (the hole-transport material or the electron-transport material) described above. In the case of using the TADF material, the S₁ level of the host material is preferably higher than the S₁ level of the TADF material. In addition, the T₁ level of the host material is preferably higher than the T₁ level of the TADF material.

Alternatively, the TADF material may be used as a host material, and a fluorescent material may be used as a guest material. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. At this time, the TADF material functions as an energy donor, and the light-emitting substance functions as an energy acceptor. Therefore, the use of the TADF material as the host material is very effective in the case where a fluorescent material is used as the guest material. In that case, the S₁ level of the TADF material is preferably higher than the S₁ level of the fluorescent material in order that high emission efficiency can be achieved. Furthermore, the T₁ level of the TADF material is preferably higher than the S₁ level of the fluorescent material. Therefore, the T₁ level of the TADF material is preferably higher than the T₁ level of the fluorescent material.

It is preferable to use a TADF material that exhibits light emission whose wavelength overlaps the wavelength on a lowest-energy-side absorption band of the fluorescent material, in which case excitation energy can be smoothly transferred from the TADF material to the fluorescent material and light emission can be efficiently obtained.

In addition, in order that singlet excitation energy is efficiently generated from the triplet excitation energy by reverse intersystem crossing, carrier recombination preferably occurs in the TADF material. It is also preferable that the triplet excitation energy generated in the TADF material not be transferred to the triplet excitation energy of the fluorescent material. For that reason, the fluorescent material preferably has a protective group around a luminophore (a skeleton which causes light emission) of the fluorescent material. As the protective group, a substituent having no π bond and saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent material have a plurality of protective groups. The substituent having no π bond has a poor carrier-transport property, whereby the TADF material and the luminophore of the fluorescent material can be made away from each other with little influence on carrier transportation or carrier recombination. Here, the luminophore refers to an atomic group (skeleton) that causes light emission in a fluorescent material. The luminophore is preferably a skeleton having a π bond, further preferably includes an aromatic ring, and still further preferably includes a condensed aromatic ring or a condensed heteroaromatic ring. Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent material including any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

### <Electron-Transport Layer>

The electron-transport layer 124 is a layer that transports electrons, which are injected from the second electrode 102, to the light-emitting layer 123.

The electron-transport layer 124 contains a third compound and a substance containing a metal.

The third compound is an electron-transport material. The electron-transport material has an electron-transport property higher than a hole-transport property.

The HOMO level of the third compound is preferably higher than or equal to −6.0 eV.

The electron mobility of the third compound is preferably higher than or equal to 1×10⁻⁷ cm²/Vs and lower than or equal to 1×10⁻⁵ cm²/Vs, further preferably higher than or equal to 1×10⁻⁷ cm²/Vs and lower than or equal to 5×10⁻⁵ cm²/Vs when the square root of electric field strength [V/cm] is 600.

The electron mobility of the third compound when the square root of the electric field strength [V/cm] is 600 is preferably lower than the electron mobility of the host material of the light-emitting layer 123 when the square root of the electric field strength [V/cm] is 600. The amount of electrons injected into the light-emitting layer 123 can be controlled by a reduction in the electron-transport property of the electron-transport layer 124, whereby the light-emitting layer 123 can be prevented from having excess electrons.

The third compound preferably includes an anthracene skeleton, and further preferably includes an anthracene skeleton and a heterocyclic skeleton. The heterocyclic skeleton is preferably a nitrogen-containing five-membered ring skeleton. It is particularly preferable that the nitrogen-containing five-membered ring skeleton include two heteroatoms in a ring, like a pyrazole ring, an imidazole ring, an oxazole ring, or, a thiazole ring.

In addition, some of the above-described electron-transport materials that can be used as the host material, and the above-described substances given as materials that can be used as the host material in combination with the above fluorescent material can be used for the electron-transport layer 124.

Examples of the third compound include 2-{4-[9,10-di(naphthalen-2-yl)-2-anthryl]phenyl}-1-phenyl-1H-benzimidazole (abbreviation: ZADN), 9-(1-naphthyl)-10-[4-(2-naphthyl)phenyl]anthracene (abbreviation: αN-βNPAnth), 9-[4-(10-phenyl-9-anthracenyl)phenyl]-9H-carbazole (abbreviation: CzPA), and 7-[4-(10-phenyl-9-anthryl)phenyl]-7H-dibenzo[c,g]carbazole (abbreviation: cgDBCzPA).

The substance containing a metal is a metal, a metallic salt, a metal oxide, or an organometallic salt.

Examples of the metal include an alkali metal, an alkaline earth metal, and a rare earth metal. Specific examples include Li, Na, K, Rb, Cs, Mg, Ca, Sr, and Ba.

Examples of the metallic salt include halides of the above metals and carbonates of the above metals. Specific examples include LiF, NaF, KF, RbF, CsF, MgF₂, CaF₂, SrF₂, BaF₂, LiCl, NaCl, KCl, RbCl, CsCl, MgCl₂, CaCl₂, SrCl₂, BaCl₂, Li₂CO₃, and Cs₂CO₃.

Examples of the metal oxide include oxides of the above metals. Specific examples include Li₂O, Na₂O, Cs₂O, MgO, and CaO.

Examples of the organometallic salt include organometallic complexes.

The substance containing a metal is preferably a metal complex containing an alkali metal or an alkaline earth metal.

The substance containing a metal is preferably a metal complex including a ligand containing nitrogen and oxygen, and an alkali metal or an alkaline earth metal.

The substance containing a metal is preferably a metal complex including a ligand having an 8-quinolinolato structure and a monovalent metal ion. The 8-quinolinolato structure is a structure in which a proton of a hydroxyl group (—OH group) in substituted or unsubstituted 8-quinolinol has been detached. Examples of the ligand having an 8-quinolinolato structure include 8-quinolinolato and methyl-substituted (e.g., 2-methyl substituted or 5-methyl substituted) 8-quinolinolato.

The substance containing a metal is preferably a lithium complex including a ligand having an 8-quinolinolato structure.

Examples of the metal complex include 8-(quinolinolato)lithium (abbreviation: Liq), 8-(quinolinolato)sodium (abbreviation: Naq), 8-(quinolinolato)potassium (abbreviation: Kq), (8-quinolinolato)magnesium (abbreviation: Mgq₂), and (8-quinolinolato)zinc (abbreviation: Znq₂).

As the substance containing a metal, Liq is particularly preferable.

As illustrated in FIG. 1E, the electron-transport layer 124 may include the electron-transport layer 124a on the light-emitting layer 123 side and the electron-transport layer 124b on the second electrode 102 side. The electron-transport layer 124a and the electron-transport layer 124b preferably differ in the concentration ratio of the third compound to the substance containing a metal. For example, the concentration of the substance containing a metal is preferably higher in the electron-transport layer 124a than in the electron-transport layer 124b. Alternatively, the concentration of the substance containing a metal may be higher in the electron-transport layer 124b than in the electron-transport layer 124a. Note that one of the electron-transport layer 124a and the electron-transport layer 124b does not necessarily contain the substance containing a metal.

### <Electron-Injection Layer>

The electron-injection layer 125 is a layer that increases the injection efficiency of electrons from the second electrode 102. The difference between the work function of the material of the second electrode 102 and the LUMO level of the material used for the electron-injection layer 125 is preferably small (0.5 eV or less).

The electron-injection layer 125 can be formed using an alkali metal, an alkaline earth metal, or a compound thereof, such as lithium, cesium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOx), or cesium carbonate. A rare earth metal compound such as erbium fluoride (ErF₃) can also be used. In addition, an electrode may be used for the electron-injection layer 125. Examples of the electrode include a substance in which electrons are added at high concentration to a mixed oxide of calcium and aluminum. Any of the above-described substances for forming the electron-transport layer 124 can also be used.

For the electron-injection layer 125, a composite material containing an electron-transport material and a donor material (an electron-donating material) may be used. Such a composite material is excellent in an electron-injection property and an electron-transport property because electrons are generated in the organic compound by the electron donor. The organic compound here is preferably a material excellent in transporting the generated electrons; specifically, for example, the above-described electron-transport materials (e.g., a metal complex or a heteroaromatic compound) can be used. As the electron donor, a substance showing a property of donating electrons to an organic compound is used. Specifically, an alkali metal, an alkaline earth metal, and a rare earth metal are preferable, and lithium, cesium, magnesium, calcium, erbium, ytterbium, and the like are given. In addition, an alkali metal oxide and an alkaline earth metal oxide are preferable, and lithium oxide, calcium oxide, barium oxide, and the like are given. Alternatively, a Lewis base such as magnesium oxide can be used. Further alternatively, an organic compound such as tetrathiafulvalene (abbreviation: TTF) can be used.

### <Charge-Generation Layer>

In the light-emitting device illustrated in FIG. 1B, the charge-generation layer 104 has a function of injecting electrons into the EL layer 103a and injecting holes into the EL layer 103b when voltage is applied between the first electrode 101 (the anode) and the second electrode 102 (the cathode).

The charge-generation layer 104 may contain a hole-transport material and an acceptor material (an electron-accepting material) or may contain an electron-transport material and a donor material. Forming the charge-generation layer 104 with such a structure can suppress an increase in the driving voltage that would be caused by stacking EL layers.

As the hole-transport material, the acceptor material, the electron-transport material, and the donor material, the above-described materials can be used.

For fabrication of the light-emitting device of one embodiment of the present invention, a vacuum process such as an evaporation method or a solution process such as a spin coating method or an ink-jet method can be used. In the case of using an evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the functional layers (the hole-injection layer, the hole-transport layer, the light-emitting layer, the electron-transport layer, the electron-injection layer, and the charge-generation layer) used in the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

Materials of the functional layers included in the light-emitting device are not limited to the above-described corresponding materials. For example, as the materials of the functional layers, a high molecular compound (e.g., an oligomer, a dendrimer, and a polymer), a middle molecular compound (a compound between a low molecular compound and a high molecular compound with a molecular weight of 400 to 4000), or an inorganic compound (e.g., a quantum dot material) may be used. As the quantum dot material, a colloidal quantum dot material, an alloyed quantum dot material, a core-shell quantum dot material, a core quantum dot material, or the like can be used.

### [Light Emission Model in Light-Emitting Device]

A light emission model of the light-emitting device that can be used for the display device of this embodiment will be described.

Here, a light emission model of a light-emitting device is described using the hole-transport layer 122, the light-emitting layer 123, and the electron-transport layer 124 illustrated in FIG. 1C. The light emission model can also be applied to a light-emitting device having a structure other than the structure in FIG. 1C.

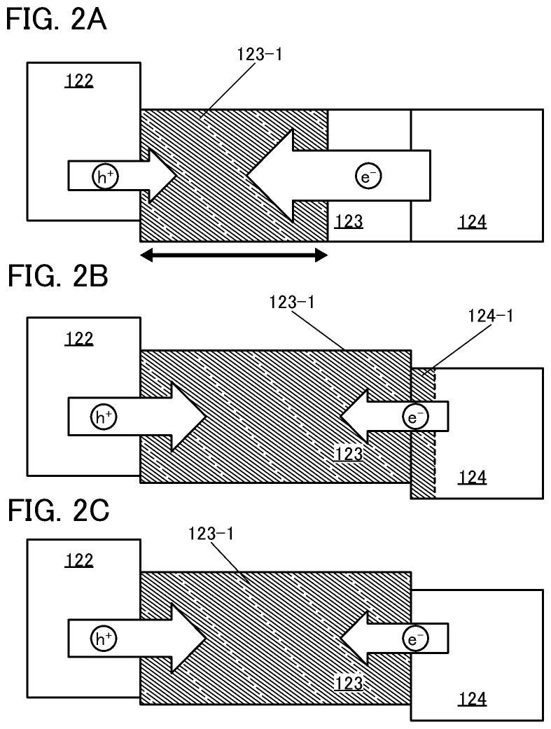

When the light-emitting layer 123 has excess electrons, a light-emitting region 123-1 is formed in a limited region of the light-emitting layer 123, as illustrated in FIG. 2A. In other words, the width of the light-emitting region 123-1 in the light-emitting layer 123 is small. Therefore, electrons (e⁻) and holes (h⁺) are recombined intensively in the limited region of the light-emitting layer 123, which accelerates degradation. In addition, the lifetime or emission efficiency may be reduced when electrons that have not been recombined in the light-emitting layer 123 pass through the light-emitting layer 123.

Meanwhile, in the light-emitting device of one embodiment of the present invention, the width of the light-emitting region 123-1 in the light-emitting layer 123 can be increased because of a low electron-transport property of the electron-transport layer 124 (FIG. 2B and FIG. 2C). Increasing the width of the light-emitting region 123-1 enables an electron-hole recombination region in the light-emitting layer 123 to be dispersed. Accordingly, a light-emitting device having a long lifetime and high emission efficiency can be provided.

At the initial driving stage of the light-emitting device of one embodiment of the present invention, a recombination region may extend to the electron-transport layer 124, as illustrated in FIG. 2B. In FIG. 2B, a recombination region in the electron-transport layer 124 is denoted by a region 124-1. Specifically, in the light-emitting device of one embodiment of the present invention, the light-emitting region 123-1 (i.e., the recombination region) may be formed in the entire light-emitting layer 123 and the recombination region may also be formed in the electron-transport layer 124, because a hole injection barrier is small at the initial driving stage and the electron-transport property of the electron-transport layer 124 is relatively low.

Since the HOMO level of the third compound contained in the electron-transport layer 124 of the light-emitting device of one embodiment of the present invention is higher than or equal to −6.0 eV, which is relatively high, some holes reach the electron-transport layer 124 to cause recombination also in the electron-transport layer 124 in some cases. Note that this phenomenon sometimes occurs when the difference in the HOMO level between the host material (or the assist material) contained in the light-emitting layer 123 and the third compound is 0.2 eV or less.

As illustrated in FIG. 2C, the carrier balance changes over the driving time of the light-emitting device of one embodiment of the present invention, and thus recombination is less likely to occur in the electron-transport layer 124. The recombination in the electron-transport layer 124 is inhibited while the light-emitting region 123-1 is formed in the entire light-emitting layer 123, whereby the energy of recombined carriers can contribute effectively to light emission. Accordingly, the luminance may increase compared to that at the initial driving stage. This luminance increase cancels out the rapid luminance decrease that appears at the initial driving stage of the light-emitting device, which is known as the initial decay; thus, the light-emitting device can have a long driving lifetime with a small initial decay. Note that in this specification and the like, the structure of the above-described light-emitting device may be referred to as a Recombination-Site Tailoring Injection structure (ReSTI structure).

The light-emitting device of one embodiment of the present invention may have a local maximum value in the decay curve of luminance obtained in a driving test under a condition with a constant current density. In other words, the light-emitting device of one embodiment of the present invention may show a behavior of luminance increase over time. This behavior can cancel out rapid degradation at the initial driving stage (i.e., initial decay). Note that the light-emitting device of one embodiment of the present invention is not limited to the above; for example, the luminance does not have a local maximum value, that is, the slope of the decay curve can be smaller without the luminance increase. Thus, when a light-emitting device has the structure showing the above behavior, the light-emitting device can have a small initial decay and an extremely long driving lifetime.

A differential value of such a decay curve having a local maximum value is 0 in a part. Therefore, a light-emitting device having a decay curve whose differential value is 0 in a part can be referred to as a light-emitting device of one embodiment of the present invention.

In the light-emitting device of one embodiment of the present invention, the electron-transport layer 124 preferably includes a portion where the mixing ratio (concentrations) of the third compound and the substance containing a metal varies in the thickness direction. Specifically, the electron-transport layer 124 preferably includes a portion where the mixing ratio (concentrations) of the electron-transport material and a metal, a metallic salt, a metal oxide, or an organometallic salt varies.

The concentration of the substance containing a metal in the electron-transport layer 124 can be estimated from the amount of atoms and molecules detected by time-of-flight secondary ion mass spectrometry (ToF-SIMS). In portions that contain the same two kinds of materials with different mixing ratios, values measured by ToF-SIMS analysis correspond to the amounts of target atoms or molecules. Therefore, comparing the detected amounts of the electron-transport material and the organometallic complex allows estimation of their mixing ratio.

In the electron-transport layer 124 in the light-emitting device of one embodiment of the present invention, the content of the substance containing a metal is preferably lower on the second electrode 102 side than on the first electrode 101 side. In other words, the electron-transport layer 124 is preferably formed such that the concentration of the substance containing a metal increases from the second electrode 102 side to the first electrode 101 side. That is, the electron-transport layer 124 includes a portion with a low concentration of the third compound on a side closer to the light-emitting layer 123 than a portion with a high concentration of the third compound is. In other words, the electron-transport layer 124 includes a portion with a high concentration of the substance containing a metal on a side closer to the light-emitting layer 123 than a portion with a low concentration of the substance containing a metal is.

In the electron-transport layer 124, the electron mobility of the portion with a high concentration of the third compound (the portion with a low concentration of the substance containing a metal) is preferably higher than or equal to 1×10⁻⁷ cm²/Vs and lower than or equal to 5×10⁻⁵ cm²/Vs when the square root of the electric field strength [V/cm] is 600.

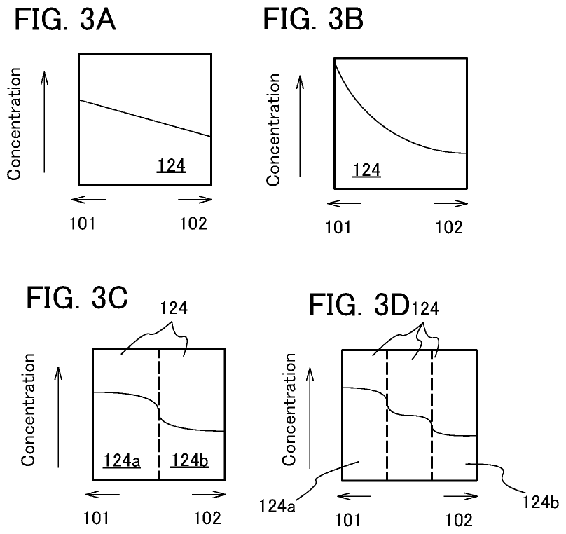

For example, the content (concentration) of the substance containing a metal in the electron-transport layer 124 can be the one as shown in each of FIG. 3A to FIG. 3D. Note that FIG. 3A and FIG. 3B show the case where a clear boundary between the contents (concentrations) of the substance containing a metal does not exist in the electron-transport layer 124, and FIG. 3C and FIG. 3D show the case where a clear boundary exists in the electron-transport layer 124.

In the case where a clear boundary does not exist in the electron-transport layer 124, the concentrations of the third compound and the substance containing a metal change continuously. FIG. 3A and FIG. 3B show examples of continuous changes in the concentration of the substance containing a metal. In the case where a clear boundary exists in the electron-transport layer 124, the concentrations of the third compound and the substance containing a metal change in a stepwise manner. FIG. 3C and FIG. 3D show examples of stepwise changes in the concentration of the substance containing a metal. Note that the case where the concentrations of the third compound and the substance containing a metal change in a stepwise manner suggests that the electron-transport layer 124 is formed of a plurality of layers. For example, FIG. 3C shows the case where the electron-transport layer 124 has a two-layer structure, and FIG. 3D shows the case where the electron-transport layer 124 has a three-layer structure. Note that in FIG. 3C and FIG. 3D, dashed lines each indicate a boundary region between layers.

A change in carrier balance in the light-emitting device of one embodiment of the present invention is probably caused by a change in electron mobility of the electron-transport layer 124.

In the light-emitting device of one embodiment of the present invention, there is a concentration difference of the substance containing a metal in the electron-transport layer 124. The electron-transport layer 124 includes a region with a high concentration of the substance containing a metal between a region with a low concentration of the substance containing a metal and the light-emitting layer 123. That is, the region with a low concentration of the substance containing a metal is positioned closer to the second electrode 102 than the region with a high concentration is.

The light-emitting device of one embodiment of the present invention having the above structure has an extremely long lifetime. In particular, the time taken for the luminance to decrease to 95% with the initial luminance being 100% (the time can also be referred to as LT95) can be extremely long.

The electron mobility of the electron-transport layer 124 changes with the concentration of the substance containing a metal. For example, as the concentration of the substance containing a metal is higher, the electron mobility of the electron-transport layer 124 is higher. In the case where two or more regions that differ in the concentration of the substance containing a metal exist in the electron-transport layer 124, the electron mobility of a region with a low concentration of the substance containing a metal is lower than the electron mobility of the other regions. The electron mobility of the electron-transport layer 124 is limited by the region with a low concentration of the substance containing a metal.

When voltage is applied to the light-emitting device for driving, the substance containing a metal sometimes diffuses to the cathode side from the anode side. For example, diffusion of the substance containing a metal from a region with a high concentration of the substance containing a metal to a region with a low concentration thereof can improve the electron mobility of the electron-transport layer. That is, the electron mobility of the electron-transport layer in the light-emitting device of one embodiment of the present invention increases with driving. This changes the carrier balance in the light-emitting device, which is accompanied by movement of the recombination region. The recombination in the electron-transport layer 124 is unlikely to occur; thus, the energy of recombined carriers can contribute effectively to light emission. Accordingly, the luminance may increase compared to that at the initial driving stage. This luminance increase cancels out the rapid luminance decrease that appears at the initial driving stage of the light-emitting device, which is known as the initial decay; thus, the light-emitting device can have a long driving lifetime with a small initial decay.

As described above, the light-emitting device of this embodiment has a structure in which holes are likely to be injected into the light-emitting layer and electrons are less likely to be injected into the light-emitting layer. Accordingly, the light-emitting device having an extremely long driving lifetime with a smaller initial decay and emitting near-infrared light can be provided.

### Embodiment 2

In this embodiment, an organometallic complex that can be used for the light-emitting device of one embodiment of the present invention will be described.

### [Structure of Organometallic Complex]

In the organometallic complex of this embodiment, a ligand including a benzoquinoxaline skeleton or a naphthoquinoxaline skeleton is coordinated to iridium that is a central metal. Specifically, the organometallic complex is represented by General Formula (G1). In particular, an organometallic complex represented by General Formula (G2) is preferable.

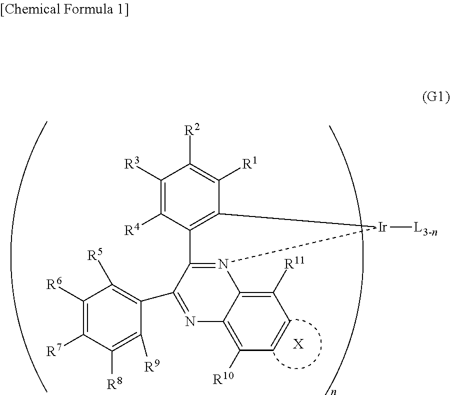

In General Formula (GT), each of R¹ to R¹¹ independently represents hydrogen or an alkyl group having 1 to 6 carbon atoms; at least two of R¹ to R⁴ represent an alkyl group having 1 to 6 carbon atoms; at least two of R⁵ to R⁹ represent an alkyl group having 1 to 6 carbon atoms; X represents a substituted or unsubstituted benzene ring or naphthalene ring; n is 2 or 3; and L represents a monoanionic ligand.

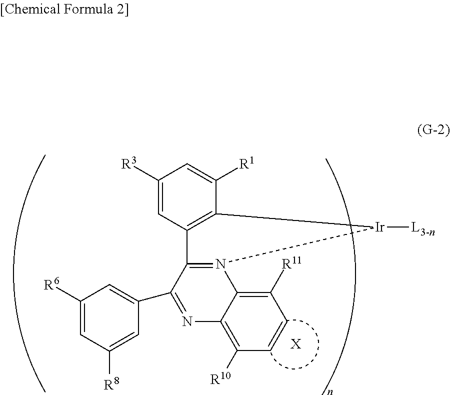

In General Formula (G2), each of R¹, R³, R⁶, and R⁸ independently represents an alkyl group having 1 to 6 carbon atoms; each of R¹⁰ and R¹¹ independently represents hydrogen or an alkyl group having 1 to 6 carbon atoms; X represents a substituted or unsubstituted benzene ring or naphthalene ring; n is 2 or 3; and L represents a monoanionic ligand.

In General Formula (G1) and General Formula (G2), X is a substituted or unsubstituted benzene ring or naphthalene ring, that is, a benzene ring or a naphthalene ring is fused to quinoxaline, whereby a t-conjugated system can be extended, the LUMO level can be deepened, and energetic stability is obtained; hence, the emission wavelength can be a long wavelength. Thus, an organometallic complex that emits near-infrared light can be obtained.

It is preferable that R¹, R³, R⁶, and R⁸ be each an alkyl group having 1 to 6 carbon atoms, in which case the sublimability of the organometallic complex increases and the sublimation temperature can be lowered, as compared to the case where R¹, R³, R⁶, and R⁸ are hydrogen. In particular, each of R¹, R³, R⁶, and R⁸ is preferably a methyl group. That is, all of R¹, R³, R⁶, and R⁸ are preferably methyl groups.

In the organometallic complex of this embodiment, X is a substituted or unsubstituted benzene ring or naphthalene ring; hence, the sublimability of the organometallic complex is likely to be low as compared to the case where X is not a condensed ring. However, since R¹, R³, R⁶, and R⁸ are each an alkyl group having 1 to 6 carbon atoms, the sublimability of the organometallic complex can be increased. Thus, an organometallic complex that has high sublimability and emits near-infrared light can be obtained.

Since R¹ and R³ are each an alkyl group having 1 to 6 carbon atoms, the dihedral angle of the benzene ring bonded to iridium can be increased. Consequently, the secondary peak in the emission spectrum of the organometallic complex can be theoretically reduced, so that the half width can be reduced. Thus, light with a desired wavelength can be obtained efficiently.

Examples of the alkyl group having 1 to 6 carbon atoms in General Formula (G1) and General Formula (G2) include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a 3-methylpentyl group, a 2-methylpentyl group, a 2-ethylbutyl group, a 1,2-dimethylbutyl group, and a 2,3-dimethylbutyl group.

When the benzene ring or the naphthalene ring has a substituent in General Formula (GT) and General Formula (G2), the substituent can be an alkyl group having 1 to 6 carbon atoms. The above description can be referred to for the alkyl group having 1 to 6 carbon atoms.

Examples of the monoanionic ligand include a monoanionic bidentate chelate ligand having a β-diketone structure, a monoanionic bidentate chelate ligand having a carboxyl group, a monoanionic bidentate chelate ligand having a phenolic hydroxyl group, a monoanionic bidentate chelate ligand in which two ligand elements are both nitrogen, and a bidentate ligand that forms a metal-carbon bond with iridium by cyclometalation.

The monoanionic ligand is preferably any one of General Formulae (L1) to (L7). In particular, the use of the ligand represented by General Formula (L1) is preferable, in which case the sublimability increases. Furthermore, the ligand represented by Structural Formula (L8) (dipivaloyl methane), which is an example of the ligand represented by General Formula (L1), and the ligand including a benzoquinoxaline skeleton or a naphthoquinoxaline skeleton form a suitable combination, which is preferable because the sublimability of the organometallic complex of this embodiment increases and the sublimation temperature can be lowered.

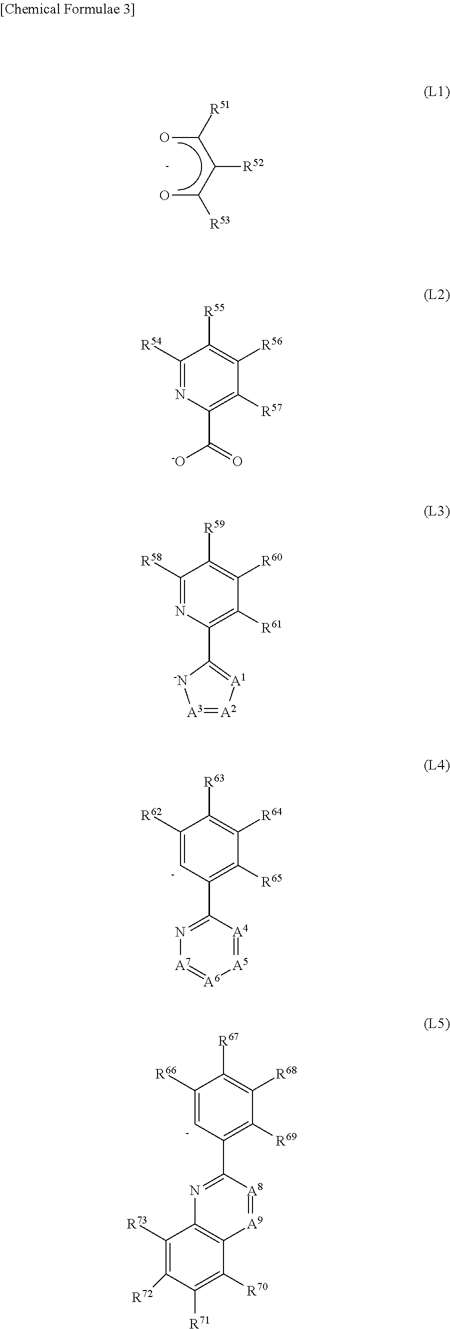

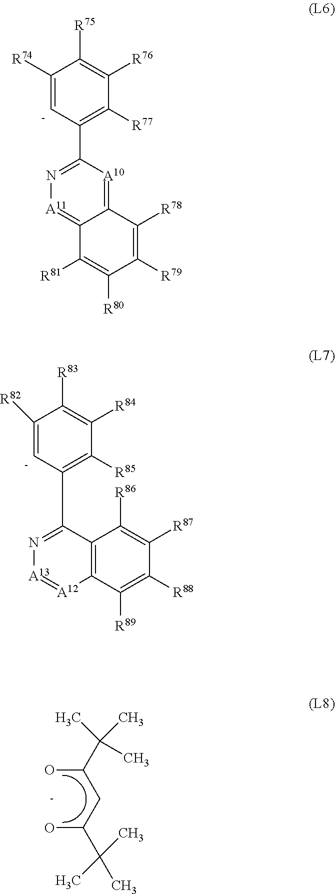

In General Formulae (L1) to (L7), each of R⁵¹ to R⁸⁹ independently represents hydrogen, a substituted or unsubstituted alkyl group having 1 to 6 carbon atoms, a halogeno group, a vinyl group, a substituted or unsubstituted haloalkyl group having 1 to 6 carbon atoms, a substituted or unsubstituted alkoxy group having 1 to 6 carbon atoms, a substituted or unsubstituted alkylthio group having 1 to 6 carbon atoms, or a substituted or unsubstituted aryl group having 6 to 13 carbon atoms; each of A¹ to A¹³ independently represents nitrogen, sp² hybridized carbon bonded to hydrogen, or sp² hybridized carbon having a substituent; and the substituent represents any of an alkyl group having 1 to 6 carbon atoms, a halogeno group, a haloalkyl group having 1 to 6 carbon atoms, and a phenyl group.

The maximum peak wavelength (i.e., the wavelength at which the peak intensity is the highest) of light emitted from the organometallic complex of this embodiment is preferably greater than or equal to 760 nm and less than or equal to 900 nm. The wavelength is particularly preferably greater than or equal to 780 nm. Moreover, the wavelength is preferably less than or equal to 880 nm.

Specific examples of the organometallic complex of this embodiment include organometallic complexes represented by Structural Formula (100) to Structural Formula (111). Note that the present invention is not limited thereto.

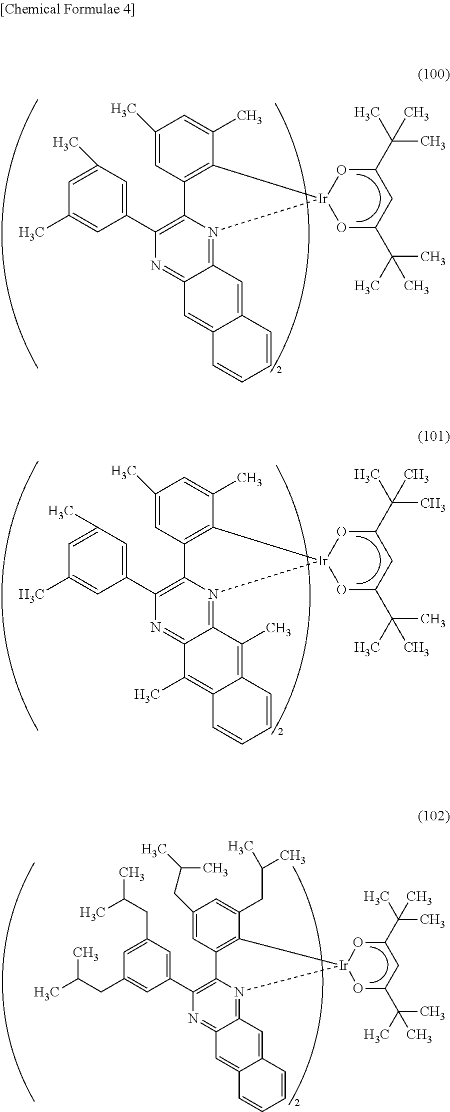

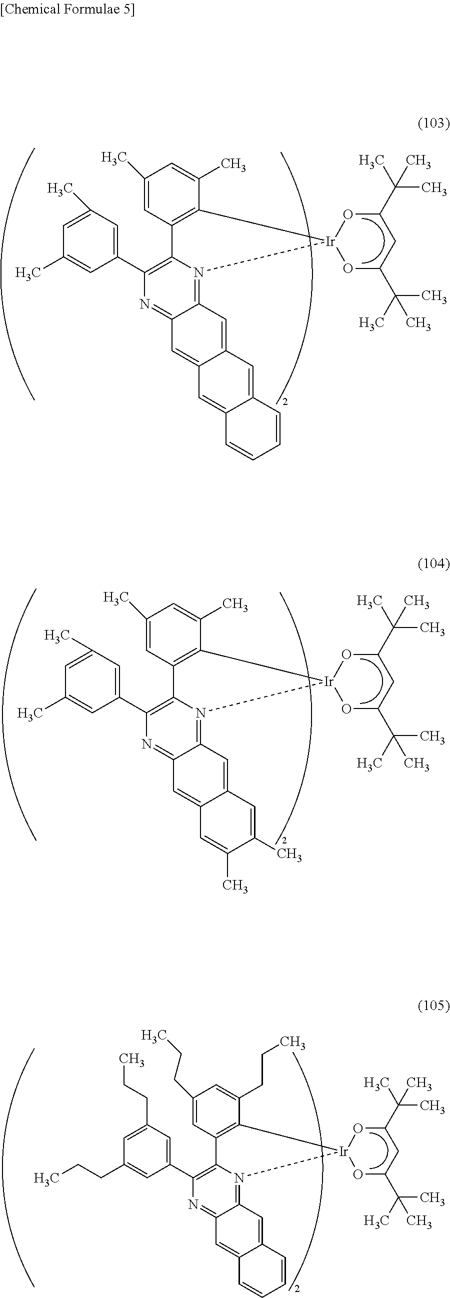

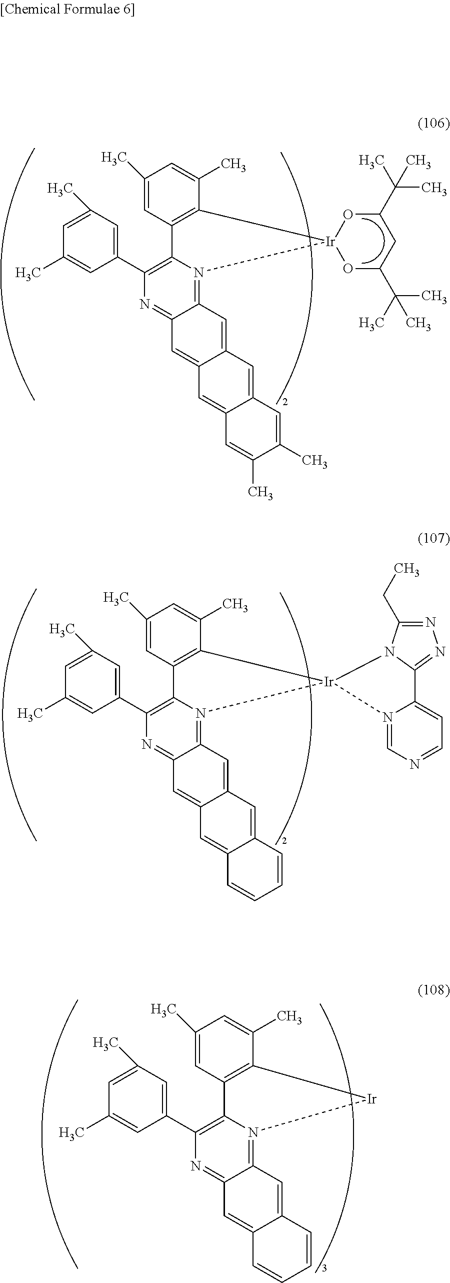

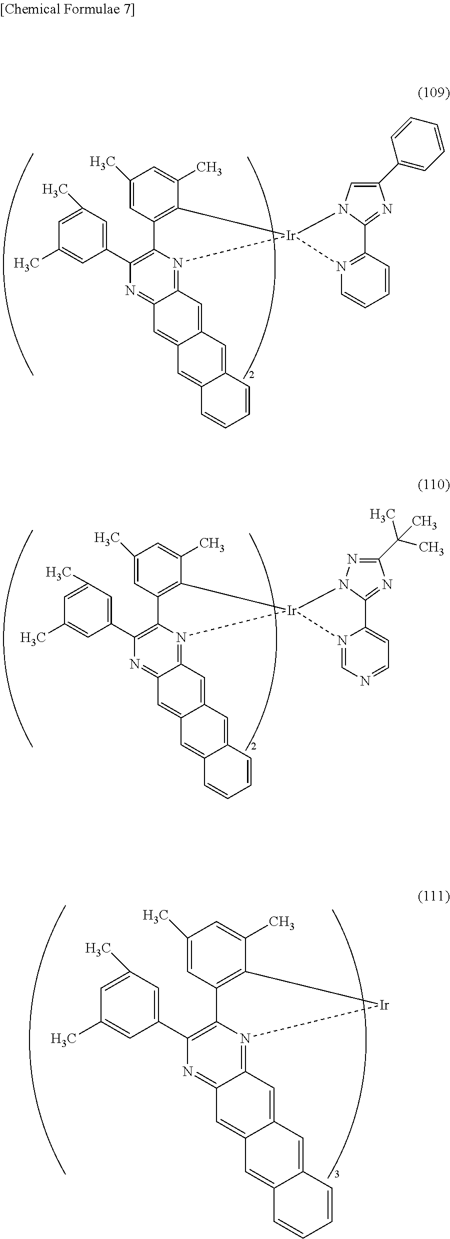

### [Method for Synthesizing Organometallic Complex]

A variety of reactions can be employed as a method for synthesizing the organometallic complex of this embodiment. An example of a method for synthesizing the organometallic complex represented by General Formula (G1) is described below.

First, an example of a method for synthesizing the organic compound represented by General Formula (G0) is described, and then, a method for synthesizing the organometallic complex represented by General Formula (G1) with the use of the organic compound represented by General Formula (G0) is described. Note that the case where n in General Formula (G1) is 2 (the organometallic complex represented by General Formula (G1-1)) and the case where n in General Formula (G1) is 3 (the organometallic complex represented by General Formula (G1-2)) are separately described below. Note that the method for synthesizing the organometallic complex of this embodiment is not limited to the synthesis methods below.

### <<Example of Method for Synthesizing Organic Compound Represented by General Formula (G0)>>

The organic compound represented by General Formula (G0) is a type of quinoxaline derivative. The organic compound represented by General Formula (G0) can be synthesized by any one of three Synthesis Schemes (A-1), (A-1′), and (A-1″) shown below, for example.

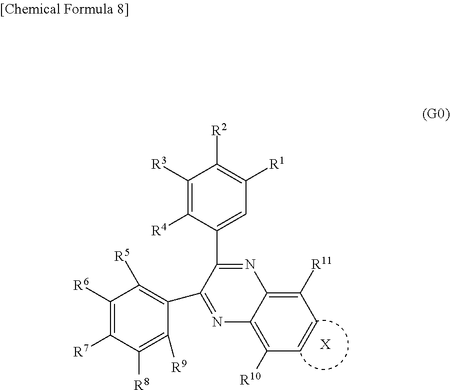

In General Formula (G0) and Synthesis Schemes (A-1), (A-1′), and (A-1″) described below, each of R¹ to R¹¹ independently represents hydrogen or an alkyl group having 1 to 6 carbon atoms; at least two of R¹ to R⁴ represent an alkyl group having 1 to 6 carbon atoms; at least two of R⁵ to R⁹ represent an alkyl group having 1 to 6 carbon atoms; and X represents a substituted or unsubstituted benzene ring or naphthalene ring.

For example, the organic compound represented by General Formula (G0) can be obtained in such a manner that a halogenated benzene derivative (A1) is lithiated with alkyllithium or the like and is reacted with a quinoxaline derivative (A2), as shown in Synthesis Scheme (A-1). In Synthesis Scheme (A-1), Z¹ represents a halogen.

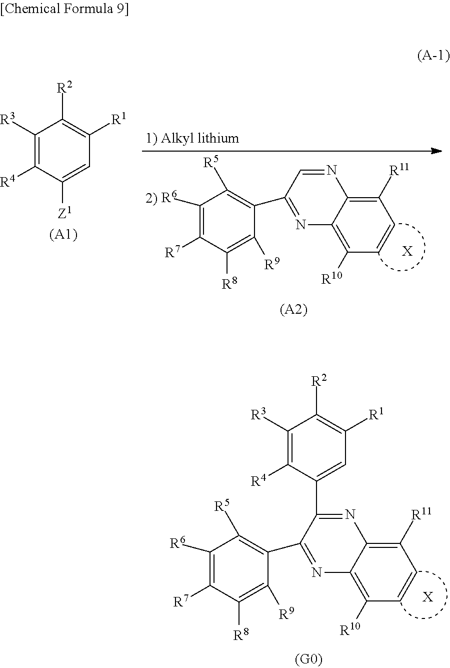

Alternatively, the organic compound represented by General Formula (G0) can be obtained by coupling of a boronic acid (A1′) of a benzene derivative and a halide (A2′) of quinoxaline, as shown in Synthesis Scheme (A-1′). In Synthesis Scheme (A-1′), Z² represents a halogen.

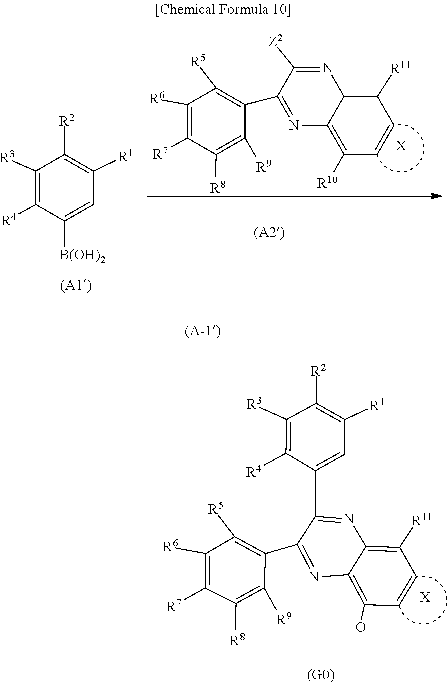

Alternatively, the organic compound represented by General Formula (G0) can be obtained by reacting diketone having benzene derivatives as substituents (A1″) with diamine (A2″), as shown in Synthesis Scheme (A-1″).

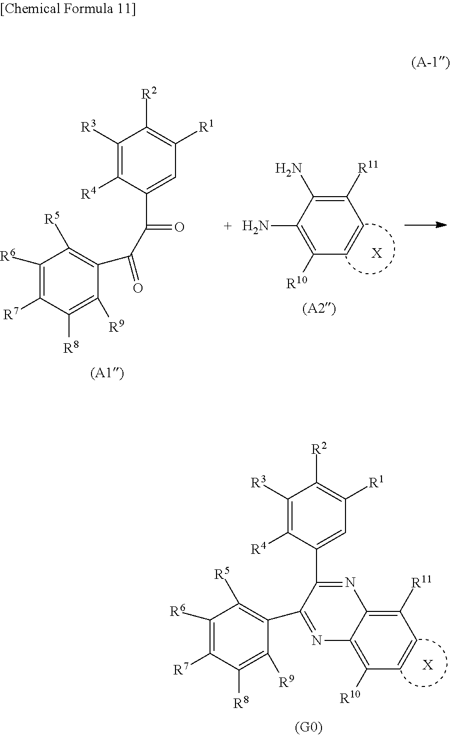

The method for synthesizing the organic compound represented by General Formula (G0) is not limited to the above-described three synthesis methods, and another method may be employed.

Since a variety of the above compounds (A1), (A2), (A1′), (A2′), (A1″), and (A2″) are commercially available or can be obtained by synthesis, various types of the organic compound represented by General Formula (G0) can be synthesized. Thus, the organometallic complex of this embodiment is characterized by having numerous variations of ligands.

### <<Method for Synthesizing Organometallic Complex Represented by General Formula (G1-1)>>

Next, an example of a method for synthesizing the organometallic complex represented by General Formula (G1-1) is described. The organometallic complex represented by General Formula (G1-1) corresponds to the case where n in General Formula (G1) is 2.

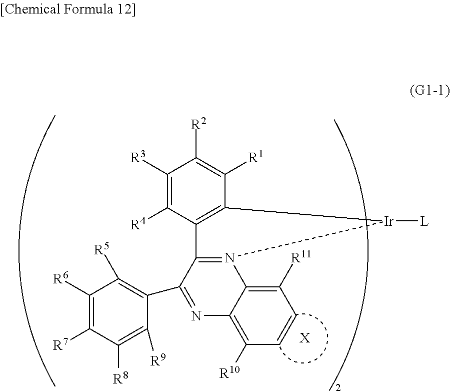

In General Formula (G1-1) and Synthesis Schemes (A-2) and (A-3) described below, each of R¹ to R¹¹ independently represents hydrogen or an alkyl group having 1 to 6 carbon atoms; at least two of R¹ to R⁴ represent an alkyl group having 1 to 6 carbon atoms; at least two of R⁵ to R⁹ represent an alkyl group having 1 to 6 carbon atoms; X represents a substituted or unsubstituted benzene ring or naphthalene ring; and L represents a monoanionic ligand.

First, as shown in Synthesis Scheme (A-2), the organic compound represented by General Formula (G0) and an iridium compound containing a halogen (e.g., iridium chloride, iridium bromide, or iridium iodide) are heated in an inert gas atmosphere using no solvent, an alcohol-based solvent (e.g., glycerol, ethylene glycol, 2-methoxyethanol, or 2-ethoxyethanol) alone, or a mixed solvent of water and one or more of the alcohol-based solvents, whereby the dinuclear complex represented by General Formula (B) can be obtained. There is no particular limitation on a heating means, and an oil bath, a sand bath, or an aluminum block may be used. Alternatively, microwaves can be used as the heating means.

The dinuclear complex represented by General Formula (B) is a type of organometallic complex having a halogen-bridged structure.

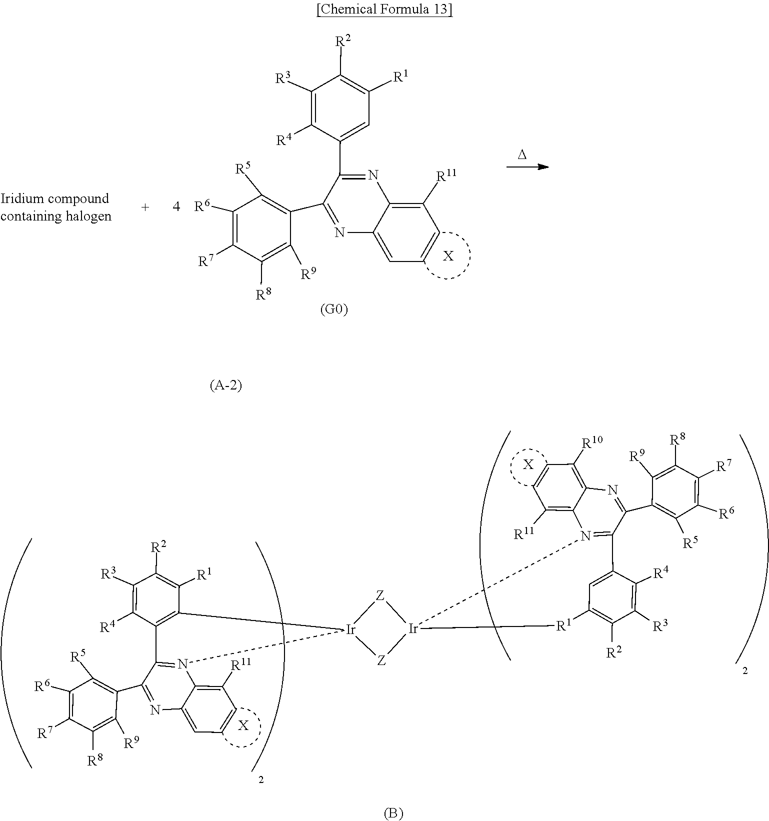

Furthermore, as shown in Synthesis Scheme (A-3), the dinuclear complex represented by General Formula (B) and HL that is a material of the monoanionic ligand are reacted in an inert gas atmosphere, whereby a proton of HL is removed and L coordinates to the central metal (Ir); thus, the organometallic complex represented by General Formula (G1-1) can be obtained. There is no particular limitation on a heating means, and an oil bath, a sand bath, or an aluminum block may be used. Alternatively, microwaves can be used as the heating means.

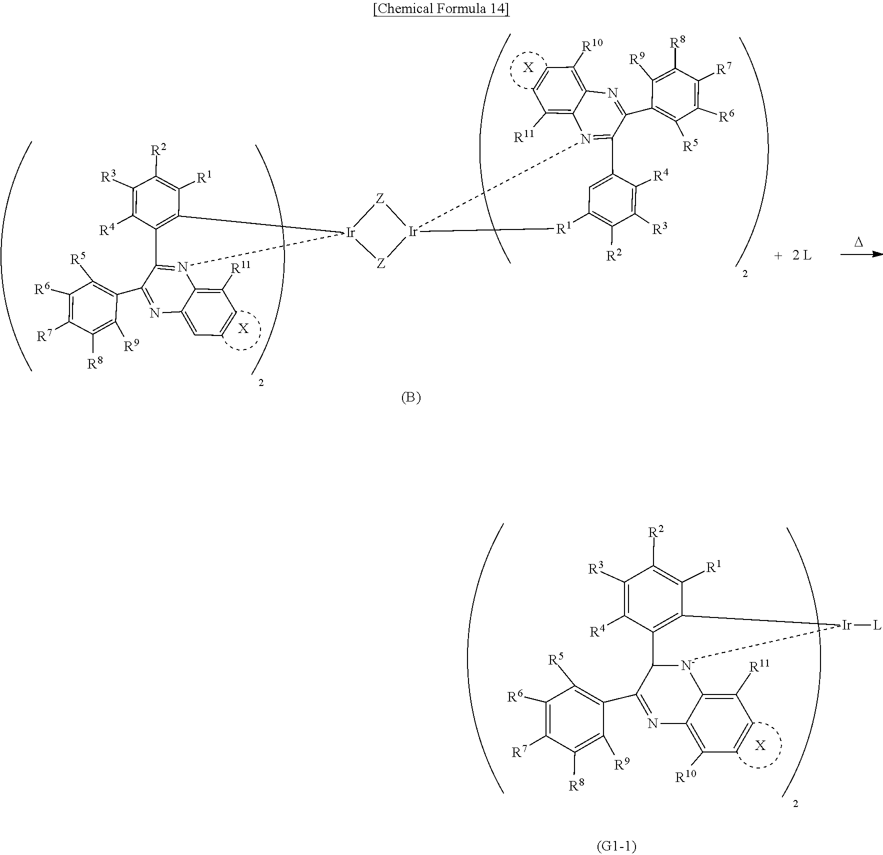

In Synthesis Schemes (A-2) and (A-3), Z represents a halogen.

### <<<Method for Synthesizing Organometallic Complex Represented by General Formula (G1-2)>>

Next, an example of a method for synthesizing the organometallic complex represented by General Formula (G1-2) is described. The organometallic complex represented by General Formula (G1-2) corresponds to the case where n in General Formula (G1) is 3.

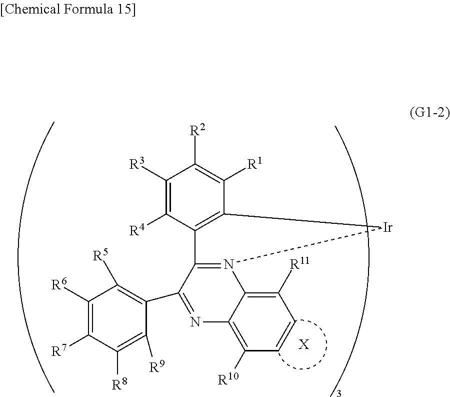

In General Formula (G1-2) and Synthesis Scheme (A-4) described below, each of R¹ to R¹¹ independently represents hydrogen or an alkyl group having 1 to 6 carbon atoms; at least two of R¹ to R⁴ represent an alkyl group having 1 to 6 carbon atoms; at least two of R⁵ to R⁹ represent an alkyl group having 1 to 6 carbon atoms; and X represents a substituted or unsubstituted benzene ring or naphthalene ring.

The organometallic complex represented by General Formula (G1-2) can be obtained in such a manner that, as shown in Synthesis Scheme (A-4), an iridium compound containing a halogen (e.g., iridium chloride hydrate, iridium bromide, iridium iodide, iridium acetate, or ammonium hexachloroiridate) or an organoiridium complex (e.g., an acetylacetonato complex, a diethyl sulfide complex, a di-μ-chloro-bridged dinuclear complex, or a di-μ-hydroxo-bridged dinuclear complex) is mixed with the organic compound represented by General Formula (G0), the mixture is dissolved in an alcohol-based solvent (e.g., glycerol, ethylene glycol, 2-methoxyethanol, or 2-ethoxyethanol) or not dissolved in any solvent, and then heating is performed.

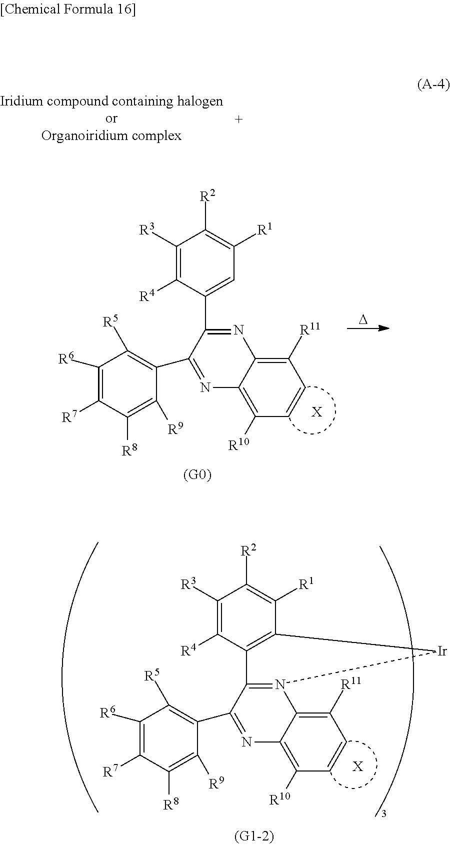

Although the method for synthesizing the organometallic complex of this embodiment is described above, the present invention is not limited thereto and synthesis may be performed by any other synthesis method.

As above, the organometallic complex of this embodiment emits near-infrared light and has high sublimability, and thus is suitable for a light-emitting material and a light-emitting device material that emit near-infrared light. The use of the organometallic complex of this embodiment can increase the emission efficiency of a light-emitting device that emits near-infrared light. Moreover, the use of the organometallic complex of this embodiment can increase the reliability of a light-emitting device that emits near-infrared light.

### Embodiment 3

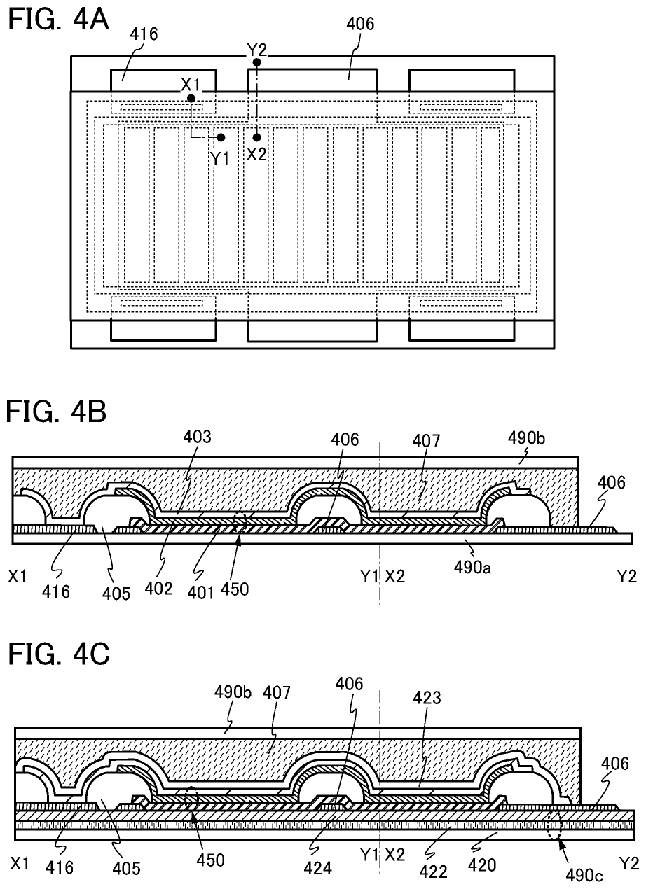

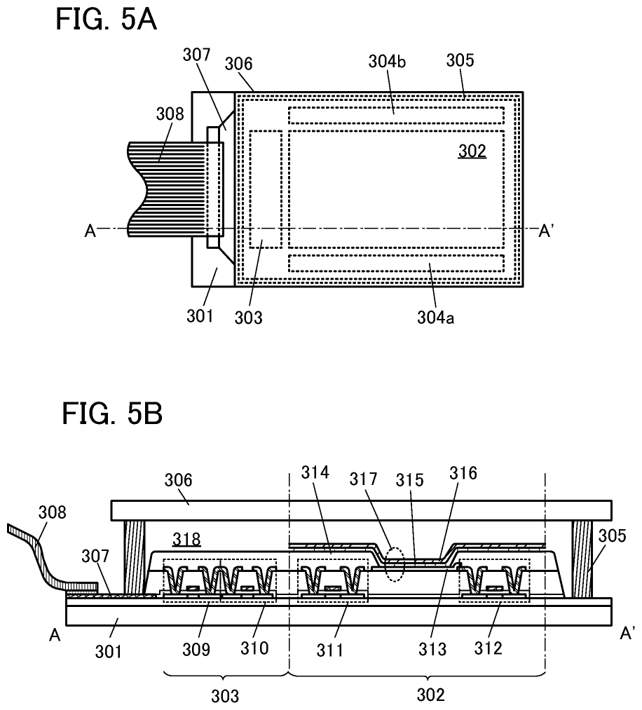

In this embodiment, a light-emitting apparatus of one embodiment of the present invention will be described with reference to FIG. 4 and FIG. 5.

The light-emitting apparatus in this embodiment includes the light-emitting device described in Embodiment 1. Thus, the reliability of the light-emitting apparatus can be increased.

### [Structure Example 1 of Light-Emitting Apparatus]

FIG. 4A is a top view of a light-emitting apparatus, and FIG. 4B and FIG. 4C are cross-sectional views along the dashed-dotted lines X1-Y1 and X2-Y2 in FIG. 4A. The light-emitting apparatus illustrated in FIG. 4A to FIG. 4C can be used as a lighting device, for example. The light-emitting apparatus can have a bottom-emission, top-emission, or dual-emission structure.

The light-emitting apparatus illustrated in FIG. 4B includes a substrate 490a, a substrate 490b, a conductive layer 406, a conductive layer 416, an insulating layer 405, an organic EL device 450 (a first electrode 401, an EL layer 402, and a second electrode 403), and an adhesive layer 407. As the organic EL device 450, the light-emitting device described in Embodiment 1 can be used.

The organic EL device 450 includes the first electrode 401 over the substrate 490a, the EL layer 402 over the first electrode 401, and the second electrode 403 over the EL layer 402. The organic EL device 450 is sealed by the substrate 490a, the adhesive layer 407, and the substrate 490b.

End portions of the first electrode 401, the conductive layer 406, and the conductive layer 416 are covered with the insulating layer 405. The conductive layer 406 is electrically connected to the first electrode 401, and the conductive layer 416 is electrically connected to the second electrode 403. The conductive layer 406 covered with the insulating layer 405 with the first electrode 401 positioned therebetween functions as an auxiliary wiring and is electrically connected to the first electrode 401. It is preferable that the auxiliary wiring electrically connected to the electrode of the organic EL device 450 be provided, in which case a voltage drop due to the resistance of the electrode can be inhibited. The conductive layer 406 may be provided over the first electrode 401. An auxiliary wiring that is electrically connected to the second electrode 403 may be provided, for example, over the insulating layer 405.

For each of the substrate 490a and the substrate 490b, glass, quartz, ceramic, sapphire, an organic resin, or the like can be used. When a flexible material is used for the substrate 490a and the substrate 490b, the flexibility of the light-emitting apparatus can be increased.

A light-emitting surface of the light-emitting apparatus may be provided with a light extraction structure for increasing the light extraction efficiency, an antistatic film inhibiting the attachment of a foreign substance, a water repellent film suppressing the attachment of stain, a hard coat film suppressing generation of a scratch in use, an impact absorption layer, or the like.

Examples of an insulating material that can be used for the insulating layer 405 include a resin such as an acrylic resin and an epoxy resin, and an inorganic insulating material such as silicon oxide, silicon oxynitride, silicon nitride oxide, silicon nitride, and aluminum oxide.

For the adhesive layer 407, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-component resin may be used. Alternatively, an adhesive sheet or the like may be used.

The light-emitting apparatus illustrated in FIG. 4C includes a barrier layer 490c, the conductive layer 406, the conductive layer 416, the insulating layer 405, the organic EL device 450, the adhesive layer 407, a barrier layer 423, and the substrate 490b.

The barrier layer 490c illustrated in FIG. 4C includes a substrate 420, an adhesive layer 422, and an insulating layer 424 having a high barrier property.

In the light-emitting apparatus illustrated in FIG. 4C, the organic EL device 450 is provided between the insulating layer 424 having a high barrier property and the barrier layer 423. Thus, even when resin films with relatively low water resistance or the like are used as the substrate 420 and the substrate 490b, a reduction in lifetime due to entry of impurities such as water into the organic EL device can be inhibited.

For each of the substrate 420 and the substrate 490b, for example, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for the substrate 420 and the substrate 490b.

An inorganic insulating film is preferably used as the insulating layer 424 having a high barrier property. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

The barrier layer 423 preferably includes at least a single-layer inorganic film. For example, the barrier layer 423 can have a single-layer structure of an inorganic film or a stacked-layer structure of an inorganic film and an organic film. As the inorganic film, the above-described inorganic insulating film is preferable. An example of the stacked-layer structure is a structure in which a silicon oxynitride film, a silicon oxide film, an organic film, a silicon oxide film, and a silicon nitride film are formed in this order. When the barrier layer has a stacked-layer structure of an inorganic film and an organic film, entry of impurities that can enter the organic EL device 450 (typically, hydrogen, water, and the like) can be suitably inhibited.

The insulating layer 424 having a high barrier property and the organic EL device 450 can be directly formed on the substrate 420 having flexibility. In that case, the adhesive layer 422 is not necessary. Alternatively, the insulating layer 424 and the organic EL device 450 can be formed over a rigid substrate with a separation layer provided therebetween and then transferred to the substrate 420. For example, the insulating layer 424 and the organic EL device 450 may be transferred to the substrate 420 in the following manner: the insulating layer 424 and the organic EL device 450 are separated from the rigid substrate by application of heat, force, laser light, or the like to the separation layer, and then the insulating layer 424 and the organic EL device 450 are bonded to the substrate 420 with the use of the adhesive layer 422. For the separation layer, a stacked-layer structure of inorganic films including a tungsten film and a silicon oxide film, or an organic resin film of polyimide or the like can be used, for example. In the case where a rigid substrate is used, the insulating layer 424 can be formed at high temperature as compared to the case where a resin substrate or the like is used; thus, the insulating layer 424 can have high density and an excellent barrier property.

### [Structure Example 2 of Light-Emitting Apparatus]

The light-emitting apparatus of one embodiment of the present invention can be of passive matrix type or active matrix type. An active-matrix light-emitting apparatus will be described with reference to FIG. 5.

FIG. 5A is a top view of the light-emitting apparatus. FIG. 5B is a cross-sectional view along the dashed-dotted line A-A′ in FIG. 5A.

The active-matrix light-emitting apparatus illustrated in FIG. 5A and FIG. 5B includes a pixel portion 302, a circuit portion 303, a circuit portion 304a, and a circuit portion 304b.

Each of the circuit portion 303, the circuit portion 304a, and the circuit portion 304b can function as a scan line driver circuit (a gate driver) or a signal line driver circuit (a source driver), or may be a circuit that electrically connects the pixel portion 302 to an external gate driver or source driver.

A lead wiring 307 is provided over a first substrate 301. The lead wiring 307 is electrically connected to an FPC 308 that is an external input terminal. The FPC 308 transmits signals (e.g., a video signal, a clock signal, a start signal, and a reset signal) and a potential from the outside to the circuit portion 303, the circuit portion 304a, and the circuit portion 304b. The FPC 308 may be provided with a printed wiring board (PWB). The structure illustrated in FIG. 5A and FIG. 5B can also be referred to as a light-emitting module including a light-emitting device (or a light-emitting apparatus) and an FPC.

The pixel portion 302 includes a plurality of pixels each including an organic EL device 317, a transistor 311, and a transistor 312. As the organic EL device 317, the light-emitting device described in Embodiment 1 can be used. The transistor 312 is electrically connected to a first electrode 313 included in the organic EL device 317. The transistor 311 functions as a switching transistor. The transistor 312 functions as a current control transistor. Note that the number of transistors included in each pixel is not particularly limited and can be set appropriately as needed.

The circuit portion 303 includes a plurality of transistors, such as a transistor 309 and a transistor 310. The circuit portion 303 may be configured with a circuit including transistors having the same conductivity type (either n-channel transistors or p-channel transistors), or may be configured with a CMOS circuit including an n-channel transistor and a p-channel transistor. Furthermore, a driver circuit may be provided outside.

There is no particular limitation on the structure of the transistor included in the light-emitting apparatus of this embodiment. For example, a planar transistor, a staggered transistor, or an inverted staggered transistor can be used. A top-gate or a bottom-gate transistor structure may be employed. Alternatively, gates may be provided above and below a semiconductor layer where a channel is formed.

There is no particular limitation on the crystallinity of a semiconductor material used for the transistor, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be inhibited.

It is preferable that the semiconductor layer of the transistor contain a metal oxide (also referred to as an oxide semiconductor). Alternatively, the semiconductor layer of the transistor may contain silicon. Examples of silicon include amorphous silicon and crystalline silicon (e.g., low-temperature polysilicon and single crystal silicon).

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin.

It is particularly preferable to use an oxide containing indium (In), gallium (Ga), and zinc (Zn) (also referred to as IGZO) for the semiconductor layer.

In the case where the semiconductor layer is an In-M-Zn oxide, a sputtering target used for depositing the In-M-Zn oxide preferably has the atomic proportion of In higher than or equal to the atomic proportion of M. Examples of the atomic ratio of the metal elements in such a sputtering target include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:6, In:M:Zn=5:1:7, In:M:Zn=5:1:8, In:M:Zn=6:1:6, and In:M:Zn=5:2:5.

The transistors included in the circuit portion 303, the circuit portion 304a, and the circuit portion 304b and the transistors included in the pixel portion 302 may have the same structure or different structures. A plurality of transistors included in the circuit portion 303, the circuit portion 304a, and the circuit portion 304b may have the same structure or two or more kinds of structures. Similarly, a plurality of transistors included in the pixel portion 302 may have the same structure or two or more kinds of structures.

An end portion of the first electrode 313 is covered with an insulating layer 314. For the insulating layer 314, an organic compound such as a negative photosensitive resin or a positive photosensitive resin (acrylic resin), or an inorganic compound such as silicon oxide, silicon oxynitride, or silicon nitride can be used. An upper end portion or a lower end portion of the insulating layer 314 preferably has a curved surface with curvature. In that case, favorable coverage with a film formed over the insulating layer 314 can be obtained.

An EL layer 315 is provided over the first electrode 313, and a second electrode 316 is provided over the EL layer 315. The EL layer 315 includes a light-emitting layer, a hole-injection layer, a hole-transport layer, an electron-transport layer, an electron-injection layer, a charge-generation layer, and the like.

The plurality of transistors and the plurality of organic EL devices 317 are sealed by the first substrate 301, a second substrate 306, and a sealant 305. A space 318 surrounded by the first substrate 301, the second substrate 306, and the sealant 305 may be filled with an inert gas (e.g., nitrogen or argon) or an organic substance (including the sealant 305).

An epoxy resin or glass frit can be used for the sealant 305. A material that transmits moisture and oxygen as little as possible is preferably used for the sealant 305. In the case where glass frit is used for the sealant, the first substrate 301 and the second substrate 306 are preferably glass substrates in terms of adhesion.

This embodiment can be combined with the other embodiments as appropriate.

### Embodiment 4

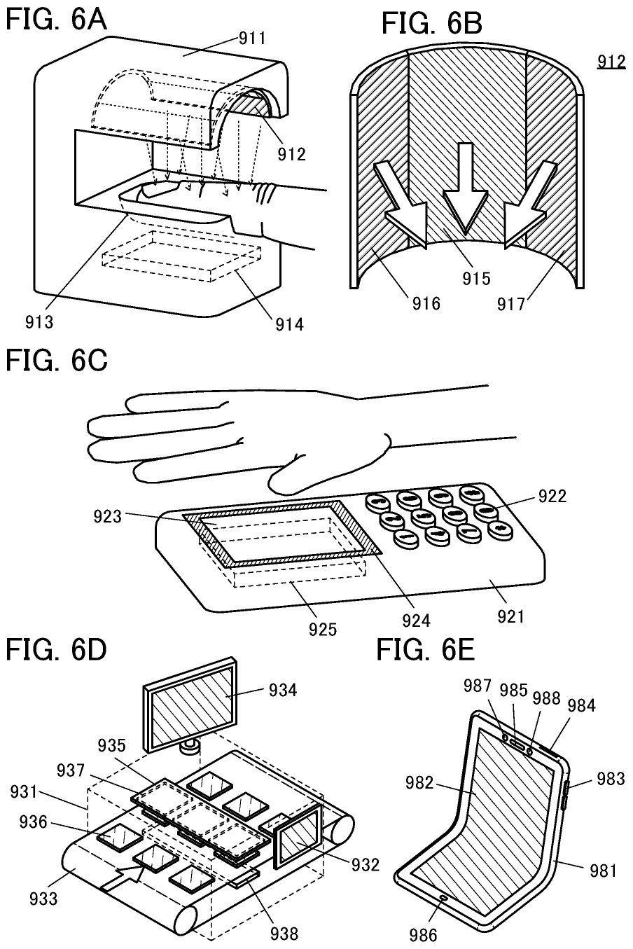

In this embodiment, electronic devices in which the light-emitting device of one embodiment of the present invention can be used will be described with reference to FIG. 6.

The electronic devices in this embodiment each include the light-emitting device described in Embodiment 1. Thus, the reliability of the electronic devices can be increased.

FIG. 6A illustrates a biometric authentication apparatus for sensing a finger vein which includes a housing 911, a light source 912, a sensing stage 913, and the like. By putting a finger on the sensing stage 913, an image of a vein pattern can be captured. The light source 912 that emits near-infrared light is provided above the sensing stage 913, and an imaging device 914 is provided under the sensing stage 913. The sensing stage 913 is formed of a material that transmits near-infrared light, and near-infrared light that is emitted from the light source 912 and passes through the finger can be captured by the imaging device 914. Note that an optical system may be provided between the sensing stage 913 and the imaging device 914. The structure of the apparatus described above can also be used for a biometric authentication apparatus for sensing a palm vein.

The light-emitting device of one embodiment of the present invention can be used for the light source 912. The light-emitting device of one embodiment of the present invention can be provided to be curved and can emit light uniformly toward a target. In particular, the light-emitting device preferably emits near-infrared light with the maximum peak intensity at a wavelength from 760 nm to 900 nm. An image is formed from received light that has passed through the finger, palm, or the like, whereby the position of the vein can be detected. This action can be utilized for biometric authentication. A combination with a global shutter system enables highly accurate sensing even for a moving target.

The light source 912 can include a plurality of light-emitting portions, such as light-emitting portions 915, 916, and 917 illustrated in FIG. 6B. The light-emitting portions 915, 916, and 917 may emit light having different wavelengths, or can emit light at different timings. Thus, by changing wavelengths and angles of light to be delivered, different images can be taken successively; hence, high level of security can be achieved using a plurality of images for the authentication.

FIG. 6C illustrates a biometric authentication apparatus for sensing a palm vein which includes a housing 921, operation buttons 922, a sensing portion 923, a light source 924 that emits near-infrared light, and the like. By holding a hand over the sensing portion 923, a palm vein pattern can be recognized. Furthermore, a security code or the like can be input with the operation buttons. The light source 924 is provided around the sensing portion 923 and irradiates a target (a hand) with light. Then, light reflected by the target enters the sensing portion 923. The light-emitting device of one embodiment of the present invention can be used for the light source 924. An imaging device 925 is provided directly under the sensing portion 923 and can capture an image of the target (an image of the whole hand). Note that an optical system may be provided between the sensing portion 923 and the imaging device 925. The structure of the apparatus described above can also be used for a biometric authentication apparatus for sensing a finger vein.

FIG. 6D illustrates a non-destructive testing apparatus that includes a housing 931, an operation panel 932, a transport mechanism 933, a monitor 934, a sensing unit 935, a light source 938 that emits near-infrared light, and the like. The light-emitting device of one embodiment of the present invention can be used for the light source 938. Test specimens 936 are transported by the transport mechanism 933 to be located directly beneath the sensing unit 935. The test specimen 936 is irradiated with near-infrared light from the light source 938, and the light passing therethrough is captured by an imaging device 937 provided in the sensing unit 935. The captured image is displayed on the monitor 934. After that, the test specimens 936 are transported to the exit of the housing 931, and defective pieces are sorted and collected. Imaging with the use of near-infrared light enables non-destructive and high-speed sensing of defective elements inside the test specimen, such as defects and foreign substances.

FIG. 6E illustrates a mobile phone that includes a housing 981, a display portion 982, an operation button 983, an external connection port 984, a speaker 985, a microphone 986, a first camera 987, a second camera 988, and the like. The display portion 982 of the mobile phone includes a touch sensor. The housing 981 and the display portion 982 have flexibility. All operations including making a call and inputting text can be performed by touch on the display portion 982 with a finger, a stylus, or the like. The first camera 987 can take a visible light image, and the second camera 988 can take an infrared light image (a near-infrared light image). The mobile phone or the display portion 982 illustrated in FIG. 6E may include the light-emitting device of one embodiment of the present invention.

This embodiment can be combined with the other embodiments as appropriate.

### Example 1

In this example, a light-emitting device of one embodiment of the present invention was fabricated and evaluation results thereof will be described.

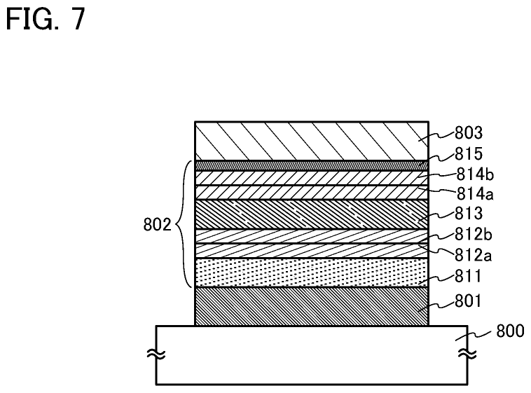

FIG. 7 illustrates the structure of a device 1 used in this example, and Table 1 shows specific structures. The chemical formulae of materials used in this example are shown below.

TABLE 1

| | | Hole- | | | Light- | Electron- | | Electron- | |
|---|---|---|---|---|---|---|---|---|---|
| | First | injection | Hole- | | emitting | transport | | injection | Second |
| | electrode | layer | transport layer | | layer | layer | | layer | electrode |
| | 801 | 811 | 812a | 812b | 813 | 814a | 814b | 815 | 803 |
| Device 1 | ITSO | BBABnf:ALD- | BBABnf | PCzN2 | * | ** | *** | Liq | Al |
| | (110 nm) | MP001Q | (115 nm) | (20 n) | | | | (1 nm) | (200 nm) |
| | | (1:0.1 10 nm) | | | | | | | |

* 9mDBtBPNfpr:PCBBiF:[Ir(dmdpbq)₂(dpm)] (0.4:0.6:0.1 40 nm)
** ZADN:Liq (0.8:1.2 17.5 nm)
*** ZADN:Liq (1.2:0.8 17.5 nm)

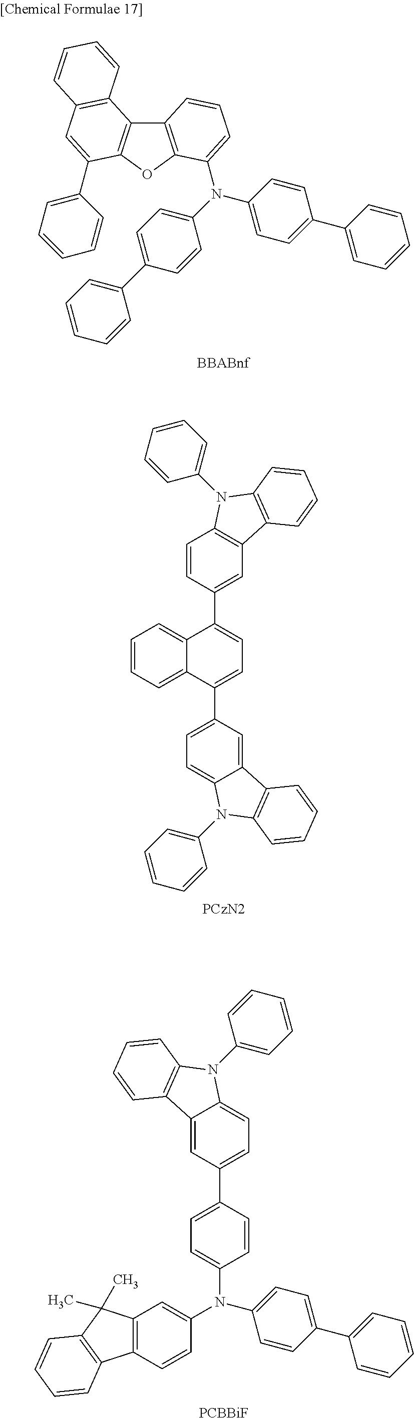

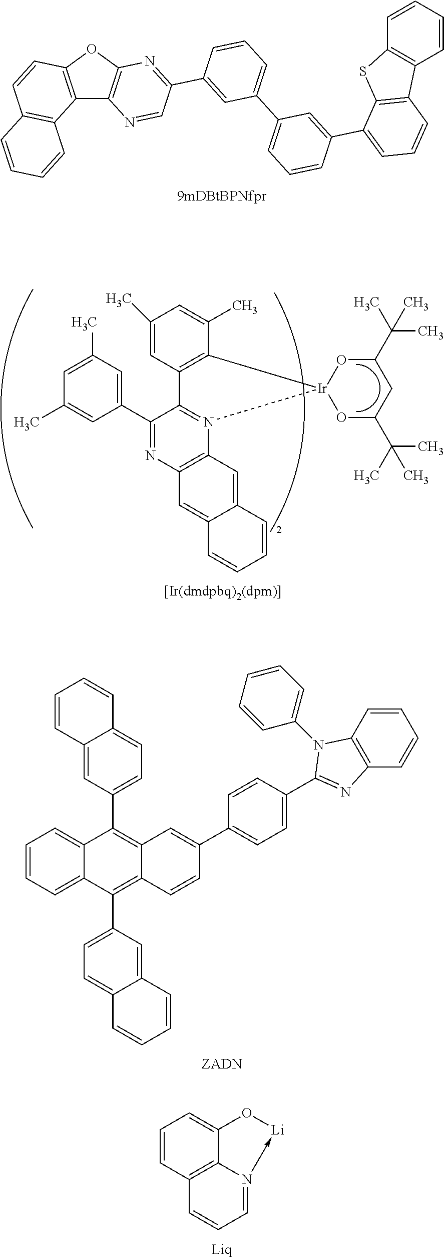

### <<Fabrication of Device 1>>

The device 1 described in this example has a structure in which a first electrode 801 is formed over a substrate 800; a hole-injection layer 811, a hole-transport layer 812a, a hole-transport layer 812b, a light-emitting layer 813, an electron-transport layer 814a, an electron-transport layer 814b, and an electron-injection layer 815 are stacked in this order over the first electrode 801; and a second electrode 803 is stacked over the electron-injection layer 815, as illustrated in FIG. 7.

First, the first electrode 801 was formed over the substrate 800. The electrode area was set to 4 mm² (2 mm×2 mm). A glass substrate was used as the substrate 800. The first electrode 801 was formed to a thickness of 110 nm using indium tin oxide containing silicon oxide (ITSO) by a sputtering method. In this example, the first electrode 801 functions as an anode.

As pretreatment, a surface of the substrate was washed with water, baking was performed at 200° C. for one hour, and then UV ozone treatment was performed for 370 seconds. After that, the substrate was transferred into a vacuum evaporation apparatus in which the pressure was reduced to approximately 10⁻⁴ Pa, vacuum baking at 170° C. for 30 minutes was performed in a heating chamber in the vacuum evaporation apparatus, and then the substrate was cooled down for approximately 30 minutes.

Next, the hole-injection layer 811 was formed over the first electrode 801. The hole-injection layer 811 was formed in such a manner that after the pressure in the vacuum evaporation apparatus was reduced to 10⁻⁴ Pa, N,N-bis(4-biphenyl)-6-phenylbenzo[b]naphtho[1,2-d]furan-8-amine (abbreviation: BBABnf) and ALD-MP001Q (produced by Analysis Atelier Corporation, serial No. 1S20180314) were deposited by co-evaporation in a weight ratio of 1:0.1 (=BBABnf:ALD-MP001Q) to have a thickness of 10 nm. ALD-MP001Q has a property of accepting electrons from BBABnf.

Then, the hole-transport layer 812a was formed over the hole-injection layer 811. The hole-transport layer 812a was formed to have a thickness of 115 nm by evaporation of BBABnf.

Then, the hole-transport layer 812b was formed over the hole-transport layer 812a. The hole-transport layer 812b was formed to have a thickness of 20 nm by evaporation of 3,3′-(naphthalene-1,4-diyl)bis(9-phenyl-9H-carbazole) (abbreviation: PCzN2).

Next, the light-emitting layer 813 was formed over the hole-transport layer 812b. The light-emitting layer 813 was deposited by co-evaporation of 9-[(3′-dibenzothiophen-4-yl)biphenyl-3-yl]naphtho[1′,2′:4,5]furo[2,3-b]pyrazine (abbreviation: 9mDBtBPNfpr), N-(1,1′-biphenyl-4-yl)-N-[4-(9-phenyl-9H-carbazol-3-yl)phenyl]-9,9-dimethyl-9H-fluoren-2-amine (abbreviation: PCBBiF), and bis{4,6-dimethyl-2-[3-(3,5-dimethylphenyl)-2-benzo[g]quinoxalinyl-κN]phenyl-κC}(2,2,6,6-tetramethyl-3,5-heptanedionato-κ²O,O′)iridium(III) (abbreviation: [Ir(dmdpbq)₂(dpm)]), which is a light-emitting substance (a phosphorescent material), such that the weight ratio of 9mDBtBPNfpr to PCBBiF and [Ir(dmdpbq)₂(dpm)] was 0.4:0.6:0.1. The thickness was set to 40 nm.

Next, the electron-transport layer 814a was formed over the light-emitting layer 813. The electron-transport layer 814a was formed to have a thickness of 17.5 nm by evaporation of 2-{4-[9,10-di(naphthalen-2-yl)-2-anthryl]phenyl}-1-phenyl-1H-benzimidazole (abbreviation: ZADN) and 8-(quinolinolato)lithium (abbreviation: Liq) (produced by Chemipro Kasei Kaisha, Ltd., serial No. 181201) in a weight ratio of 0.8:1.2 (=ZADN:Liq).

Then, the electron-transport layer 814b was formed over the electron-transport layer 814a. The electron-transport layer 814b was formed to have a thickness of 17.5 nm by evaporation of ZADN and Liq in a weight ratio of 1.2:0.8 (=ZADN:Liq).

Then, the electron-injection layer 815 was formed over the electron-transport layer 814b. The electron-injection layer 815 was formed to have a thickness of 1 nm by evaporation of Liq.

Next, the second electrode 803 was formed over the electron-injection layer 815. The second electrode 803 was formed to have a thickness of 200 nm by an evaporation method using aluminum. In this example, the second electrode 803 functions as a cathode.

Through the above steps, the light-emitting device in which an EL layer 802 was provided between the pair of electrodes over the substrate 800 was fabricated. The hole-injection layer 811, the hole-transport layer 812a, the hole-transport layer 812b, the light-emitting layer 813, the electron-transport layer 814a, the electron-transport layer 814b, and the electron-injection layer 815 described in the above steps are functional layers forming the EL layer in one embodiment of the present invention. Furthermore, in all the evaporation steps in the above fabrication method, an evaporation method by a resistance-heating method was used.

The light-emitting device fabricated as described above was sealed using a different substrate (not illustrated). At the time of the sealing using the different substrate (not illustrated), the different substrate (not illustrated) on which an adhesive that is solidified by ultraviolet light was applied was fixed onto the substrate 800 in a glove box containing a nitrogen atmosphere, and the substrates were bonded to each other such that the adhesive was attached to the periphery of the light-emitting device formed over the substrate 800. At the time of the sealing, the adhesive was irradiated with 365-nm ultraviolet light at 6 J/cm² to be solidified, and the adhesive was subjected to heat treatment at 80° C. for one hour to be stabilized.

### <<Operation Characteristics of Device 1>>

The operation characteristics of the device 1 were measured. Note that the measurement was performed at room temperature (an atmosphere kept at 25° C.) with a near-infrared spectroradiometer (SR-NIR, manufactured by TOPCON TECHNOHOUSE CORPORATION).

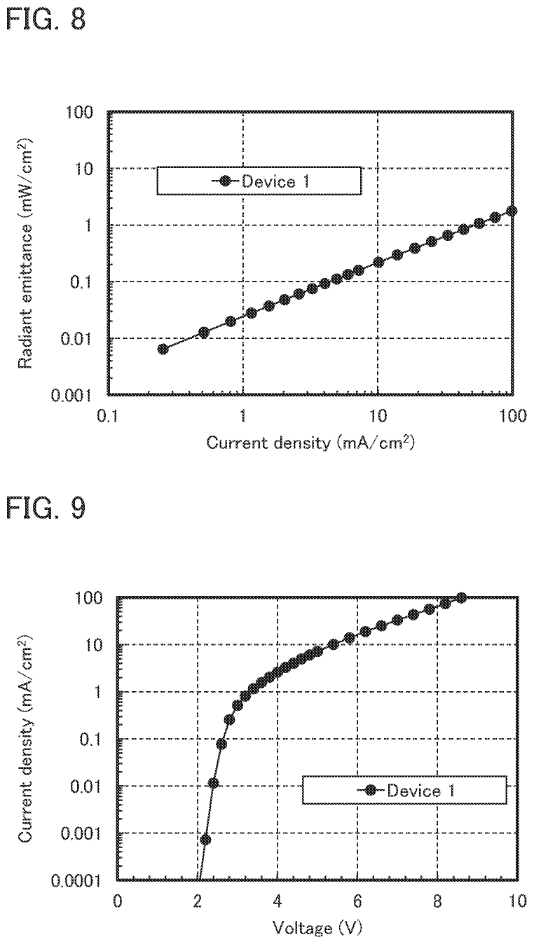

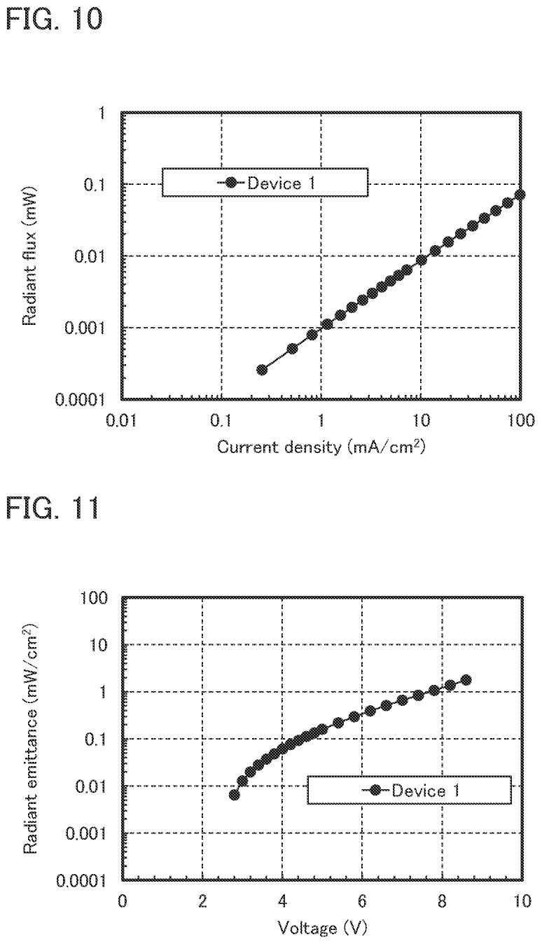

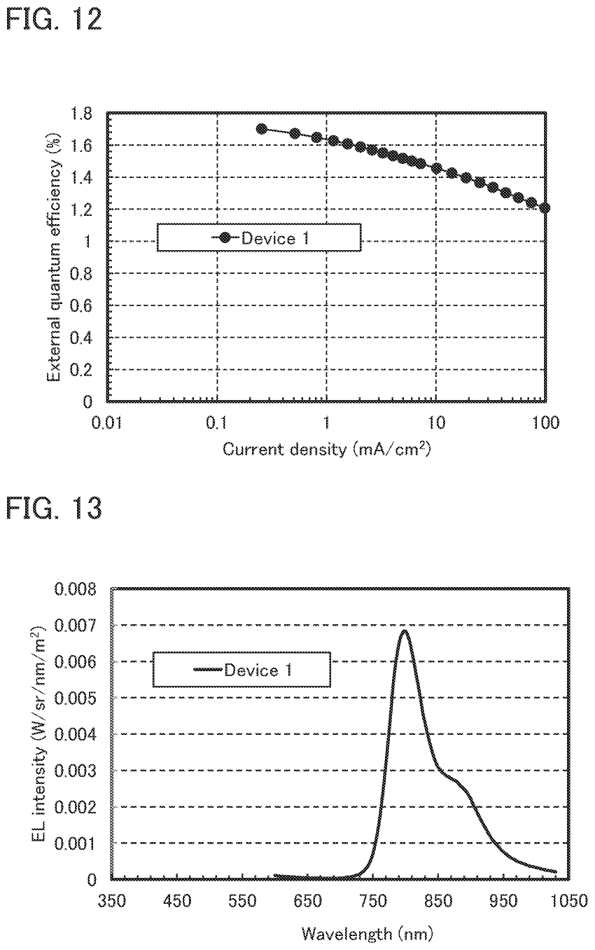

FIG. 8 shows the current density-radiant emittance characteristics of the device 1. FIG. 9 shows the voltage-current density characteristics of the device 1. FIG. 10 shows the current density-radiant flux characteristics of the device 1. FIG. 11 shows the voltage-radiant emittance characteristics of the device 1. FIG. 12 shows the current density-external quantum efficiency characteristics of the device 1. Note that radiant emittance, radiant flux, and external quantum efficiency were calculated using radiance, assuming that the device had Lambertian light-distribution characteristics.

Table 2 lists the initial values of main characteristics of the device 1 at a current density of around 10 mA/cm².

TABLE 2

| | | | | | | External |
|---|---|---|---|---|---|---|
| | | | Current | | Radiant | quantum |
| | Voltage | Current | density | Radiance | flux | efficiency |
| | (V) | (mA) | (mA/cm²) | (W/sr/M²) | (mW) | (%) |
| Device 1 | 5.4 | 0.41 | 10 | 0.70 | 0.0090 | 1.5 |

The device 1 was found to exhibit favorable characteristics, as shown in FIG. 8 to FIG. 12 and Table 2.

FIG. 13 shows an emission spectrum when current at a current density of 10 mA/cm² was supplied to the device 1. As shown in FIG. 13, the device 1 exhibited an emission spectrum having a maximum peak at around 798 nm, which was derived from light emitted from [Ir(dmdpbq)₂(dpm)] contained in the light-emitting layer 813.

### <<Reliability Test on Device 1>>

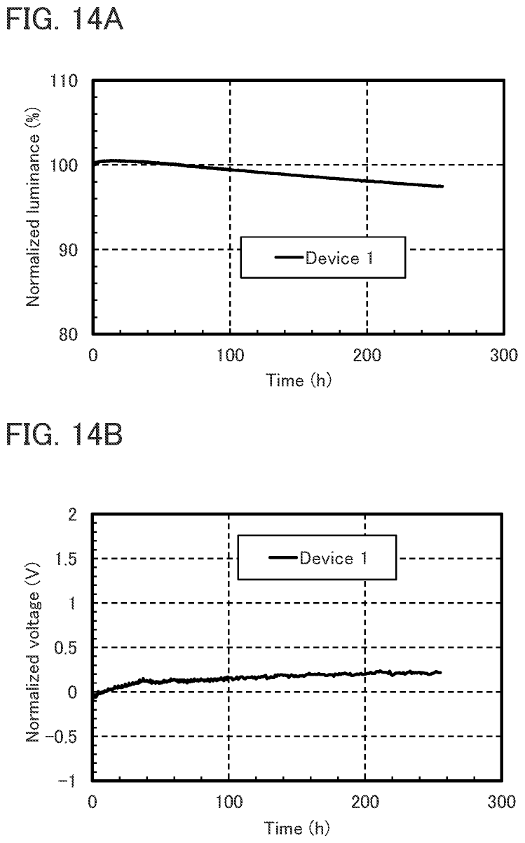

Next, a reliability test was performed on the device 1. FIG. 14A and FIG. 14B show the results of the reliability test. In FIG. 14A, the vertical axis represents normalized luminance (%) with an initial luminance of 100%, and the horizontal axis represents driving time (h). In FIG. 14B, the vertical axis represents normalized voltage (V) with an initial voltage of 0, and the horizontal axis represents driving time (h). In the reliability test, the device 1 was driven at a current density of 75 mA/cm².

FIG. 14A reveals that the device 1 has a small initial luminance decay, a small long-term change in luminance, and high reliability.

In the decay curve of the device 1, the luminance increases at the initial stage, showing that the decay curve has a local maximum value. The device 1 showing such a degradation behavior has an extremely long lifetime with a smaller initial decay.

FIG. 14B shows that a long-term change in voltage is small and voltage is less likely to increase in the device 1.

### <Reference Example 1>

In this reference example, methods for calculating the HOMO level, the LUMO level, and the electron mobility of an organic compound in the light-emitting device of one embodiment of the present invention will be described.

The HOMO level and the LUMO level can be calculated through cyclic voltammetry (CV) measurement.

In this reference example, an electrochemical analyzer (model number: ALS model 600A or 600C, manufactured by BAS Inc.) was used as a measurement apparatus. To prepare a solution for the CV measurement, dehydrated dimethylformamide (DMF) (manufactured by Sigma-Aldrich Inc., 99.8%, catalog No. 22705-6) was used as a solvent, tetra-n-butylammonium perchlorate (n-Bu₄NClO₄) (manufactured by Tokyo Chemical Industry Co., Ltd., catalog No. T0836) as a supporting electrolyte was dissolved at a concentration of 100 mmol/L, and the object to be measured was dissolved at a concentration of 2 mmol/L. A platinum electrode (PTE platinum electrode, manufactured by BAS Inc.) was used as a working electrode, another platinum electrode (Pt counter electrode for VC-3 (5 cm), manufactured by BAS Inc.) was used as an auxiliary electrode, and an Ag/Ag⁺ electrode (RE7 reference electrode for non-aqueous solvent, manufactured by BAS Inc.) was used as a reference electrode. The measurement was conducted at room temperature (20 to 25° C.). The scan speed in the CV measurement was fixed to 0.1 V/sec, and an oxidation potential Ea [V] and a reduction potential Ec [V] with respect to the reference electrode were measured. Ea is an intermediate potential of an oxidation-reduction wave, and Ec is an intermediate potential of a reduction-oxidation wave. Here, since the potential energy of the reference electrode used in this reference example with respect to the vacuum level is known to be −4.94 eV, the HOMO level and the LUMO level can be calculated by the following formulae: HOMO level [eV]=−4.94−Ea and LUMO level [eV]=−4.94−Ec.

The electron mobility can be measured by an impedance spectroscopy method (IS method).

As a method for measuring the carrier mobility of an EL material, a time-of-flight method (TOF method), a method (SCLC method) using I-V characteristics of a space-charge-limited current (SCLC), or the like has been known for a long time. The TOF method needs a sample with a much larger thickness than that of an actual organic EL device. The SCLC method has a disadvantage in that electric field strength dependence of carrier mobility cannot be obtained, for example. Since an organic film required for the measurement employing the IS method is as thin as approximately several hundreds of nanometers, the film can be formed using a relatively small amount of EL materials; accordingly, the IS method is characterized by the capability of measuring the mobility with a thickness close to the thickness of a film in an actual organic EL device, and can also measure the electric field strength dependence of the carrier mobility.

In the IS method, a micro sinusoidal voltage signal (V=V₀[exp(jωt)]) is applied to an EL device, and the impedance (Z=V/I) of the EL device is obtained from a phase difference between the current amplitude of a response current signal (I=I₀exp[(ωt+ϕ)]) and the input signal. By applying the voltage to the EL device while the frequency of the voltage is changed from a high level to a low level, components having various relaxation times that contribute to the impedance can be separated and measured.

Here, admittance Y (=1/Z), which is the reciprocal number of the impedance, can be represented by conductance G and susceptance B as shown in the following formula (1).

$$\begin{matrix}[ Formula 1 ] & \\ Y = \frac{1}{Z} = G + jB & ( 1 )\end{matrix}$$

In addition, by a single injection model, calculation of the following formulae (2) and (3) can be performed. Here, g (the formula (4)) is differential conductance. In the formulae, C represents capacitance, θ is ωT and represents a transit angle, and ω represents angular frequency. T represents transit time. For the analysis, the current equation, the Poisson's equation, and the current continuity equation are used, and a diffusion current and a trap state are ignored.

$$\begin{matrix}[ Formulae 2 ] & \\ G = \frac{g {θ}^{3}}{6} \frac{θ - sin θ}{{( θ - sin θ )}^{2} + {( \frac{{θ}^{2}}{2} + cos θ - 1 )}^{2}} & ( 2 ) \\ B = ω C = \frac{g {θ}^{3}}{6} \frac{\frac{{θ}^{2}}{2} + cos θ - 1}{{( θ - sin θ )}^{2} + {( \frac{{θ}^{2}}{2} + cos θ - 1 )}^{2}} & ( 3 ) \\ g = \frac{9}{4} ɛ μ \frac{{V}_{0}}{{d}^{3}} & ( 4 )\end{matrix}$$

A method for calculating mobility from the frequency characteristics of capacitance is a −ΔB method. A method for calculating mobility from the frequency characteristics of conductance is a ωΔG method.

In practice, first, an electron-only device is fabricated using a material whose electron mobility is intended to be calculated. The electron-only device is a device designed such that only electrons flow therein as carriers. In this specification, the method for calculating mobility from the frequency characteristics of capacitance (the −ΔB method) is described.

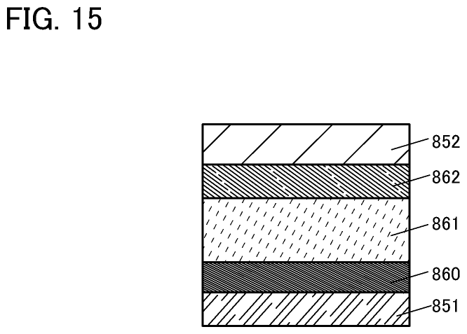

FIG. 15 illustrates a structure of an electron-only device fabricated for the measurement, and Table 3 shows its specific components. The electron-only device fabricated in this reference example includes a first layer 860, a second layer 861, and a third layer 862 between a first electrode 851 (anode) and a second electrode 852 (cathode). The material whose electron mobility is intended to be calculated is used as a material for the second layer 861. In this reference example, the electron mobility of a film formed by co-evaporation of 2-{4-[9,10-di(naphthalen-2-yl)-2-anthryl]phenyl}-1-phenyl-1H-benzimidazole (abbreviation: ZADN) and 8-(quinolinolato)lithium (abbreviation: Liq) in a weight ratio of 1:1 was measured. In this reference example, the electron mobilities of 7-[4-(10-phenyl-9-anthryl)phenyl]-7H-dibenzo[c,g]carbazole (abbreviation: cgDBCzPA) and 2-[3′-(dibenzothiophen-4-yl)biphenyl-3-yl]dibenzo[f,h]quinoxaline (abbreviation: 2mDBTBPDBq-II) were also measured.

TABLE 3

| First electrode | | | First | Second | Third | Second electrode |
|---|---|---|---|---|---|---|
| (anode) | | | layer | layer | layer | (cathode) |
| 100 nm | 50 nm | 100 nm | 1 nm | 200 nm | 1 nm | 100 nm |
| APC | ITSO | Al | Liq | ZADN:Liq | Liq | Al |
| | | | | (0.5:0.5) | | |

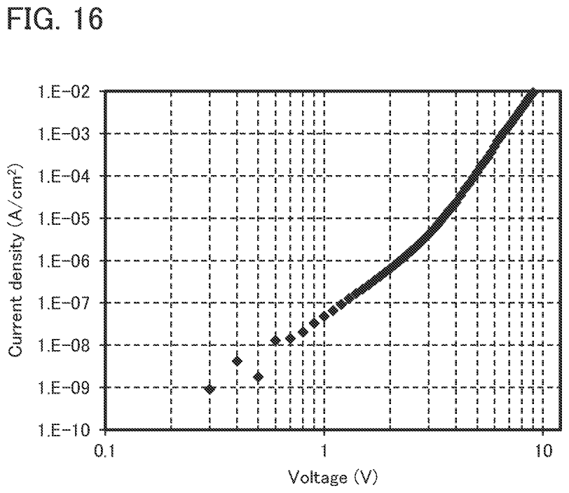

FIG. 16 shows the current density-voltage characteristics of the electron-only device using the film formed by co-evaporation of ZADN and Liq as the second layer 861.

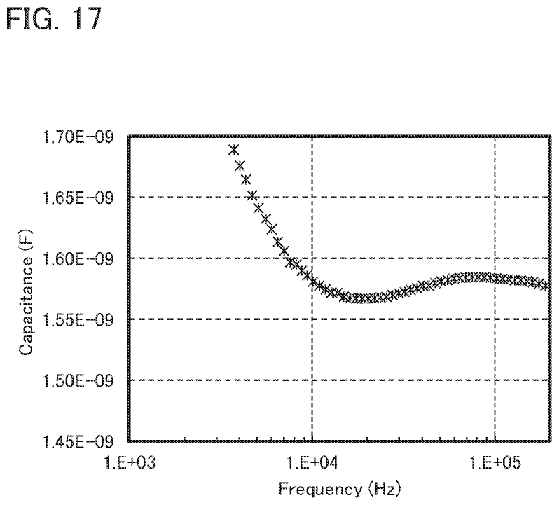

The impedance was measured under the conditions where the DC voltage was applied in the range of 5.0 V to 9.0 V, the AC voltage was 70 mV, and the frequency was 1 Hz to 3 MHz. Here, capacitance is calculated from admittance, which is the reciprocal number of the obtained impedance (the above formula (1)). FIG. 17 shows the frequency characteristics of the calculated capacitance C when the application voltage was 7.0 V.

The frequency characteristics of the capacitance C are obtained from a phase difference in current, which is caused because a space charge generated by carriers injected by the micro voltage signal cannot completely follow the micro AC voltage. The transit time of the carriers in the film is defined by time T taken for the injected carriers to reach the counter electrode, and is represented by the following formula (5).

$$\begin{matrix}[ Formula 3 ] & \\ T = \frac{4}{3} \frac{{L}^{2}}{μ {V}_{0}} & ( 5 )\end{matrix}$$

A negative susceptance change (−ΔB) corresponds to a value (−ωΔC) obtained by multiplying a capacitance change −ΔC by angular frequency ω. According to the formula (3), there is a relation between peak frequency on the lowest frequency side ƒ′ₘₐₓ (=ωₘₐₓ/2π) and the transit time T as shown in the following formula (6).

$$\begin{matrix}[ Formula 4 ] & \\ T = \frac{4.5}{2 π {f}_{max}^{′}} & ( 6 )\end{matrix}$$

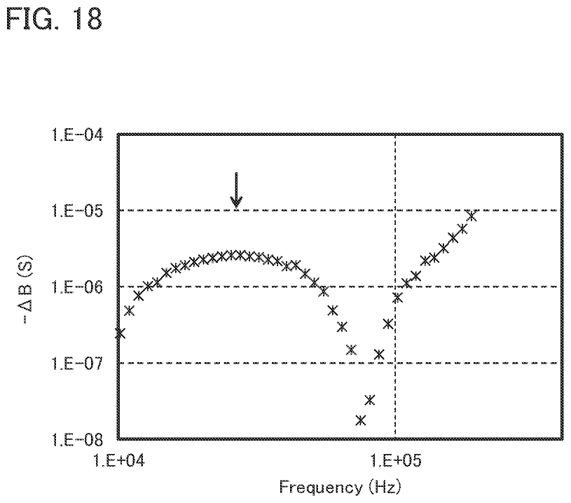

FIG. 18 shows the frequency characteristics of −ΔB calculated from the above measurement (i.e., −ΔB at a DC voltage of 7.0 V). The peak frequency on the lowest frequency side ƒ′ₘₐₓ is indicated by an arrow in FIG. 18.

The transit time T is obtained from ƒ′ₘₐₓ obtained from the above measurement and analysis (the formula (6)); thus, in this example, the electron mobility at a voltage of 7.0 V can be obtained from the above formula (5). Through the same measurement with the DC voltage in the range of 5.0 V to 9.0 V, the electron mobility at each voltage (electric field strength) can be calculated, so that the electric field strength dependence of the mobility can also be measured.

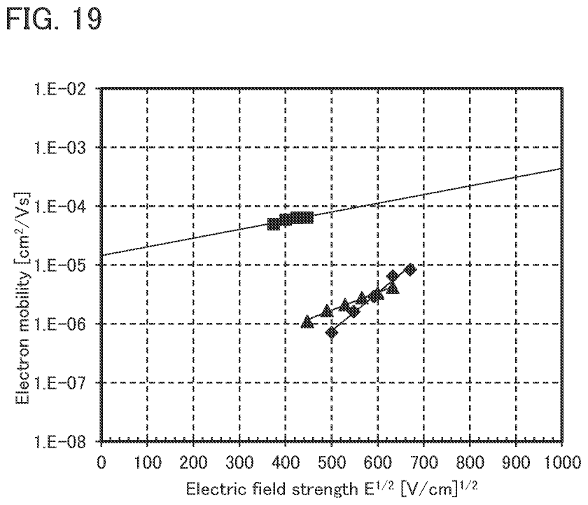

FIG. 19 shows the final electric field strength dependence of the electron mobility of the organic compounds obtained by the above calculation method, and Table 4 shows the values of the electron mobility read from the diagram when the square root of the electric field strength [V/cm] was 600 [V/cm]^{1/2}. In FIG. 19, squares represent the result of cgDBCzPA, triangles represent the result of 2mDBTBPDBq-II, and rhombuses represent the result of the film formed by co-evaporation of ZADN and Liq.

TABLE 4

| | Electron mobility (cm²/Vs) |
|---|---|
| cgDBCzPA | 7.7 × 10⁻⁵ |
| 2mDBTBPDBq-II | 2.2 × 10⁻⁵ |
| ZADN:Liq (1:1) | 3.5 × 10⁻⁶ |

The electron mobility can be calculated as described above. For the details about the measurement method, refer to the following reference: Takayuki Okachi et al., Japanese Journal of Applied Physics, vol. 47, No. 12, 2008, pp. 8965-8972.

### <Reference Example 2>

A method for synthesizing bis{4,6-dimethyl-2-[3-(3,5-dimethylphenyl)-2-benzo[g]quinoxalinyl-κN]phenyl-κC}(2,2,6,6-tetramethyl-3,5-heptanedionato-κ²O,O′)iridium(III) (abbreviation: [Ir(dmdpbq)₂(dpm)]) that was used in Example 1 above will be specifically described. The structure of [Ir(dmdpbq)₂(dpm)] is shown below.

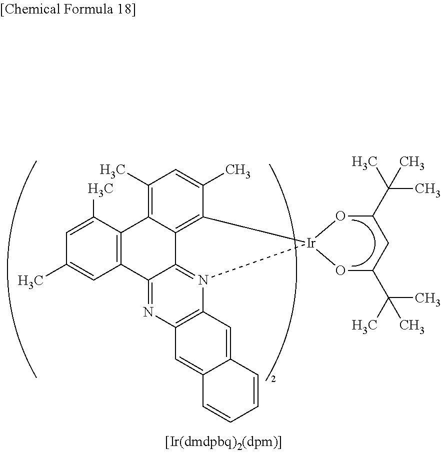

### Step 1; Synthesis of 2,3-bis-(3,5-dimethylphenyl)-2-benzo[g]quinoxaline (abbreviation: Hdmdpbq

First, in Step 1, Hdmdpbq was synthesized. Into a three-neck flask equipped with a reflux pipe, 3.20 g of 3,3′,5,5′-tetramethylbenzyl, 1.97 g of 2,3-diaminonaphthalene, and 60 mL of ethanol were put, the air in the flask was replaced with nitrogen, and then the mixture was stirred at 90° C. for 7.5 hours. After a predetermined time elapsed, the solvent was distilled off. Then, purification by silica gel column chromatography using toluene as a developing solvent was performed, whereby the target substance was obtained (a yellow solid, yield: 3.73 g, percent yield: 79%). The synthesis scheme of Step 1 is shown in (a-1).

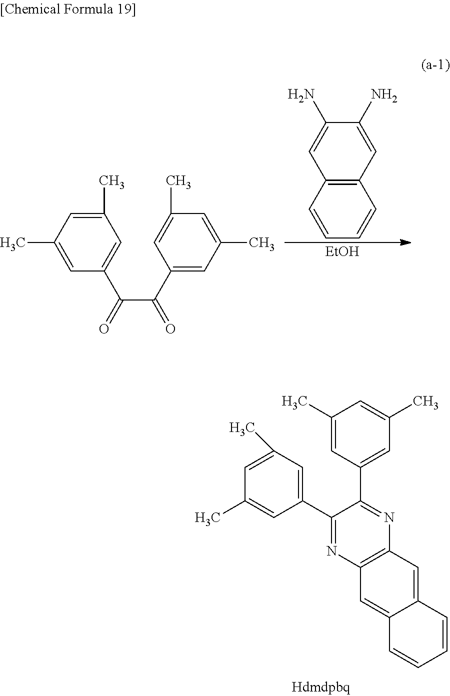

Analysis results by nuclear magnetic resonance spectroscopy (¹H-NMR) of the yellow solid obtained in Step 1 are shown below. The analysis results revealed that Hdmdpbq was obtained.

Given below is ¹H NMR data of the obtained substance.

¹H-NMR. δ (CD₂Cl₂): 2.28 (s, 12H), 7.01 (s, 2H), 7.16 (s, 4H), 7.56-7.58 (m, 2H), 8.11-8.13 (m, 2H), 8.74 (s, 2H).

### Step 2; Synthesis of di-μ-chloro-tetrakis{4,6-dimethyl-2-[3-(3,5-dimethylphenyl)-2-benzo[g]quinoxalinyl-κN]phenyl-κC}diiridium(III) (abbreviation: [Ir(dmdpbq)₂Cl]₂

Next, in Step 2, [Ir(dmdpbq)₂Cl]₂ was synthesized. Into a recovery flask equipped with a reflux pipe, 15 mL of 2-ethoxyethanol, 5 mL of water, 1.81 g of Hdmdpbq obtained in Step 1, and 0.66 g of iridium chloride hydrate (IrCl₃—H₂O) (produced by Furuya Metal Co., Ltd.) were put, and the air in the flask was replaced with argon. Then, microwave irradiation (2.45 GHz, 100 W) was performed for 2 hours to cause reaction. After a predetermined time elapsed, the obtained residue was suction-filtered and washed with methanol, whereby the target substance was obtained (a black solid, yield: 1.76 g, percent yield: 81%). The synthesis scheme of Step 2 is shown in (a-2).

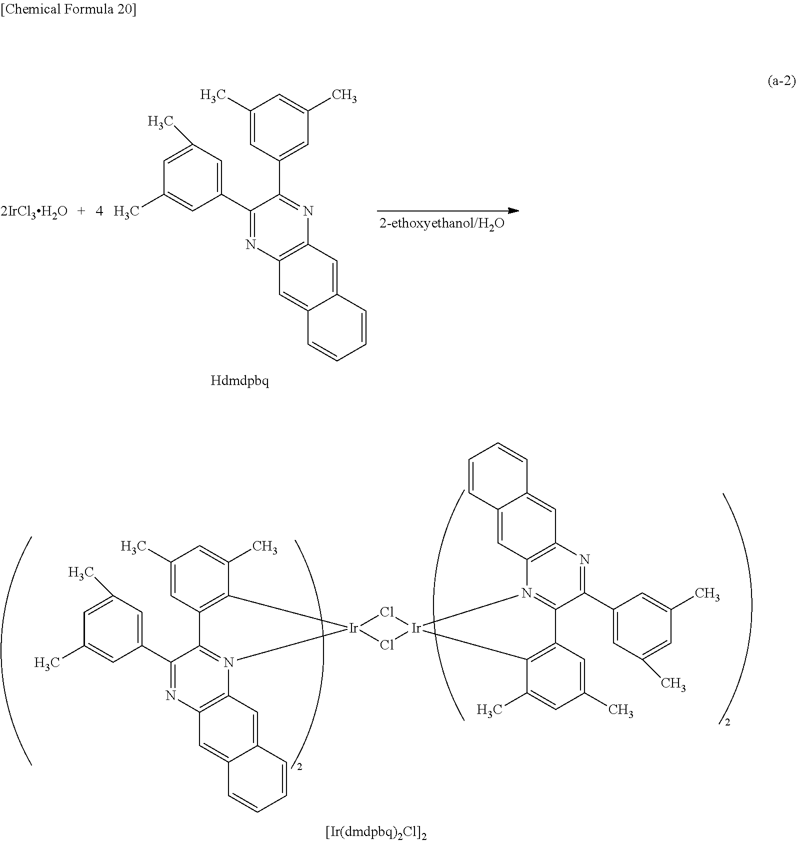

### Step 3; Synthesis of [Ir(dmdpbq)₂(dpm)]

Then, in Step 3, [Ir(dmdpbq)₂(dpm)] was synthesized. Into a recovery flask equipped with a reflux pipe, 20 mL of 2-ethoxyethanol, 1.75 g of [Ir(dmdpbq)₂Cl]₂ obtained in Step 2, 0.50 g of dipivaloylmethane (abbreviation: Hdpm), and 0.95 g of sodium carbonate were put, and the air in the flask was replaced with argon. Then, microwave irradiation (2.45 GHz, 100 W) was performed for 3 hours. The obtained residue was suction-filtered with methanol and then washed with water and methanol. The obtained solid was purified by silica gel column chromatography using dichloromethane as a developing solvent, and then recrystallization was performed with a mixed solvent of dichloromethane and methanol, whereby the target substance was obtained (a dark green solid, yield: 0.42 g, percent yield: 21%). With a train sublimation method, 0.41 g of the obtained dark green solid was purified by sublimation. The conditions of the sublimation purification were such that the dark green solid was heated under a pressure of 2.7 Pa at 300° C. while the argon gas flowed at a flow rate of 10.5 mL/min. After the sublimation purification, a dark green solid was obtained in a percent yield of 78%. The synthesis scheme of Step 3 is shown in (a-3).

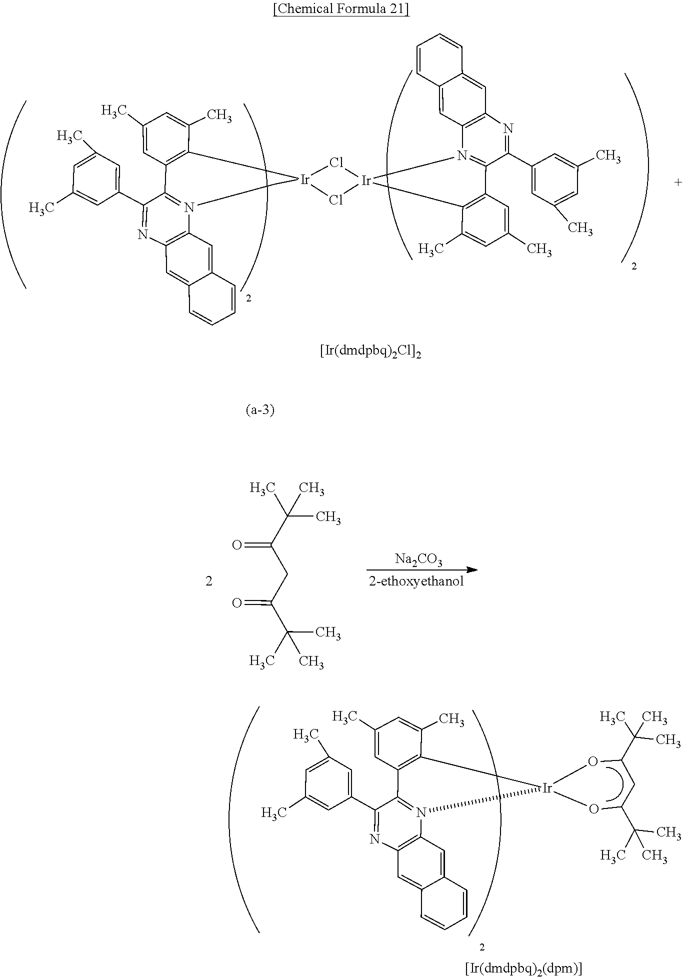

Analysis results by nuclear magnetic resonance spectroscopy (¹H-NMR) of the dark green solid obtained in Step 3 are shown below. The analysis results revealed that [Ir(dmdpbq)₂(dpm)] was obtained.

¹H-NMR. δ (CD₂Cl₂): 0.75 (s, 18H), 0.97 (s, 6H), 2.01 (s, 6H), 2.52 (s, 12H), 4.86 (s, 1H), 6.39 (s, 2H), 7.15 (s, 2H), 7.31 (s, 2H), 7.44-7.51 (m, 4H), 7.80 (d, 2H), 7.86 (s, 4H), 8.04 (d, 2H), 8.42 (s, 2H), 8.58 (s, 2H).

### REFERENCE NUMERALS

101: first electrode, 102: second electrode, 103: EL layer, 103a: EL layer, 103b: EL layer, 104: charge-generation layer, 121: hole-injection layer, 122: hole-transport layer, 122a: hole-transport layer, 122b: hole-transport layer, 123: light-emitting layer, 123-1: light-emitting region, 124: electron-transport layer, 124-1: region, 124a: electron-transport layer, 124b: electron-transport layer, 125: electron-injection layer, 301: substrate, 302: pixel portion, 303: circuit portion, 304a: circuit portion, 304b: circuit portion, 305: sealant, 306: substrate, 307: wiring, 308: FPC, 309: transistor, 310: transistor, 311: transistor, 312: transistor, 313: first electrode, 314: insulating layer, 315: EL layer, 316: second electrode, 317: organic EL device, 318: space, 401: first electrode, 402: EL layer, 403: second electrode, 405: insulating layer, 406: conductive layer, 407: adhesive layer, 416: conductive layer, 420: substrate, 422: adhesive layer, 423: barrier layer, 424: insulating layer, 450: organic EL device, 490a: substrate, 490b: substrate, 490c: barrier layer, 800: substrate, 801: first electrode, 802: EL layer, 803: second electrode, 811: hole-injection layer, 812a: hole-transport layer, 812b: hole-transport layer, 813: light-emitting layer, 814a: electron-transport layer, 814b: electron-transport layer, 815: electron-injection layer, 851: first electrode, 852: second electrode, 860: first layer, 861: second layer, 862: third layer, 911: housing, 912: light source, 913: sensing stage, 914: imaging device, 915: light-emitting portion, 916: light-emitting portion, 917: light-emitting portion, 921: housing, 922: operation button, 923: sensing portion, 924: light source, 925: imaging device, 931: housing, 932: operation panel, 933: transport mechanism, 934: monitor, 935: sensing unit, 936: test specimen, 937: imaging device, 938: light source, 981: housing, 982: display portion, 983: operation button, 984: external connection port, 985: speaker, 986: microphone, 987: camera, 988: camera

1. A light-emitting device comprising:
a hole-injection layer, a light-emitting layer, and an electron-transport layer in this order between a pair of electrodes,
wherein the hole-injection layer comprises a first compound and a second compound,
wherein the first compound has a property of accepting an electron from the second compound,
wherein the second compound has a HOMO level higher than or equal to −5.7 eV and lower than or equal to −5.4 eV,
wherein the light-emitting layer comprises a light-emitting organic compound,
wherein the maximum peak wavelength of light emitted from the light-emitting organic compound is greater than or equal to 760 nm and less than or equal to 900 nm,
wherein the electron-transport layer comprises a third compound and a substance comprising a metal,
wherein the third compound is an electron-transport material, and
wherein the substance comprising a metal is a metal, a metallic salt, a metal oxide, or an organometallic salt.

2. The light-emitting device according to claim 1,
wherein the third compound has a HOMO level higher than or equal to −6.0 eV.

3. The light-emitting device according to claim 1,
wherein the electron-transport layer comprises a first region and a second region,
wherein the first region is positioned closer to the light-emitting layer than the second region is, and
wherein the first region and the second region differ in a concentration of the substance comprising a metal.

4. The light-emitting device according to claim 3,
wherein the concentration of the substance comprising a metal is higher in the first region than in the second region.

5. The light-emitting device according to claim 3,
wherein the second region does not comprise the substance comprising a metal.

6. The light-emitting device according to claim 3,
wherein the concentration of the substance comprising a metal is higher in the second region than in the first region.

7. The light-emitting device according to claim 3,
wherein the first region does not comprise the substance comprising a metal.

8. The light-emitting device according to claim 1,
wherein the light-emitting layer further comprises a fourth compound and a fifth compound, and
wherein a combination of the fourth compound and the fifth compound forms an exciplex.

9. The light-emitting device according to claim 8,
wherein the fourth compound is a hole-transport material, and
wherein the fifth compound is an electron-transport material.

10. The light-emitting device according to claim 1, further comprising a hole-transport layer,
wherein the hole-transport layer is positioned between the hole-injection layer and the light-emitting layer,
wherein the hole-transport layer comprises a sixth compound,
wherein a HOMO level of the sixth compound is lower than or equal to the HOMO level of the second compound, and
wherein a difference between the HOMO level of the sixth compound and the HOMO level of the second compound is 0.2 eV or less.

11. The light-emitting device according to claim 10,
wherein the second compound and the sixth compound each comprise at least one of a carbazole skeleton, a dibenzofuran skeleton, a dibenzothiophene skeleton, and an anthracene skeleton.

12. The light-emitting device according to claim 10,
wherein the second compound and the sixth compound are the same compound.

13. The light-emitting device according to claim 1,
wherein the substance comprising a metal is a metal complex comprising an alkali metal or an alkaline earth metal.

14. The light-emitting device according to claim 1,
wherein the substance comprising a metal is a metal complex comprising a ligand comprising nitrogen and oxygen and an alkali metal or an alkaline earth metal.

15. The light-emitting device according to claim 1,
wherein the substance comprising a metal is a metal complex comprising a monovalent metal ion and a ligand having an 8-quinolinolato structure.

16. The light-emitting device according to claim 1,
wherein the substance comprising a metal is a lithium complex comprising a ligand having an 8-quinolinolato structure.

17. The light-emitting device according to claim 1,
wherein the light-emitting organic compound is an organometallic complex having a metal-carbon bond.

18. The light-emitting device according to claim 17,
wherein the organometallic complex comprises a condensed heteroaromatic ring comprising 2 to 5 rings, and
wherein the condensed heteroaromatic ring is coordinated to the metal.

19. The light-emitting device according to claim 1,
wherein the light-emitting organic compound is a cyclometalated complex.

20. The light-emitting device according to claim 1,
wherein the light-emitting organic compound is an orthometalated complex.

21. The light-emitting device according to claim 1,
wherein the light-emitting organic compound is an iridium complex.

22. The light-emitting device according to claim 1,
wherein the maximum peak wavelength of the light emitted from the light-emitting organic compound is greater than or equal to 780 nm and less than or equal to 880 nm.

23. A light-emitting apparatus comprising:
the light-emitting device according to claim 1; and
one or both of a transistor and a substrate.

24. A light-emitting module comprising:
the light-emitting apparatus according to claim 23; and
one or both of a connector and an integrated circuit.

25. An electronic device comprising:
the light-emitting module according to claim 24; and
at least one of an antenna, a battery, a housing, a camera, a speaker, a microphone, and an operation button.

26. A lighting device comprising:
the light-emitting apparatus according to claim 23; and
at least one of a housing, a cover, and a support.
